(19) United States
(12) Patent Application Publication
(10) Pub. No.: US 2026/0153571 A1
(43) Pub. Date: Jun. 4, 2026

(54) DEVICE FOR DETECTING A MAGNETIC FIELD AND SYSTEM FOR MEASURING A MAGNETIC FIELD COMPRISING SUCH A DEVICE

(71) Applicant: Commissariat à l'Energie Atomique et aux Energies Alternatives, Paris (FR)

(72) Inventor: Jean-Pierre NIKOLOVSKI, Grenoble (FR)

(21) Appl. No.: 19/403,433

(22) Filed: Nov. 28, 2025

(30) Foreign Application Priority Data
Dec. 3, 2024 (FR) 2413365

(51) Int. Cl. G01R 33/028; G01R 33/00

(52) U.S. Cl. CPC G01R 33/028; G01R 33/0041

(57) ABSTRACT

The present description concerns a system (10) for measuring a magnetic field (B_{z}) comprising a magnetic field detection device (20) comprising a tapered acoustic waveguide (40), an electrically-conductive wire (50) rigidly coupled to a tapered end of the guide, and an electroacoustic transducer (60) rigidly coupled to the base of the guide; and a control and acquisition device (30) coupled to the magnetic field detection device comprising a generator (33I) supplying a pair of current pulses of opposite directions or a plurality of frequency-modulated current pulses to the conductive wire and an acquisition circuit (32) detecting electrical signals (S) supplied by the electroacoustic transducer or a generator supplying a pair of voltage pulses of opposite signs or a plurality of frequency-modulated voltage pulses controlling the electroacoustic transducer and an acquisition circuit detecting electrical

### TECHNICAL FIELD

The present disclosure generally concerns the measurement of static or time-varying magnetic fields.

### PRIOR ART

For certain applications, it would be desirable to be able to measure a static or time-varying magnetic field with a spatial resolution smaller than 0.2 mm. Further, for certain applications, it would be desirable to be able to measure a time-varying magnetic field, in particular a pulsed or high-frequency magnetic field. Further, for certain applications, it would be desirable to be able to measure with a same device a low-intensity or high-intensity magnetic field.

Document US20240230795 describes a magnetic field detection device comprising a tapered acoustic waveguide having a base and a first tapered end, an electrically-conductive wire rigidly coupled to the tapered end, and an electroacoustic transducer rigidly coupled to the base. Such a device is adapted to the measurement of static or time-varying magnetic fields with a spatial resolution smaller than 0.2 mm.

Although such a detection device is fully satisfactory for many applications, it would be desirable for it to be able to allow measurement of weak magnetic fields, particularly those with an amplitude lower than the magnetic field of the Earth, and to achieve a resolution lower than one microTesla.

### SUMMARY OF THE INVENTION

An embodiment overcomes all or part of the disadvantages of known magnetic field detection devices and magnetic field measurement systems comprising such devices.

An object of an embodiment is for the magnetic field detection device to allow measurement of a weak magnetic field.

An object of an embodiment is for the magnetic field detection device to have a resolution lower than one microTesla.

An embodiment provides a magnetic field measurement system comprising:
a device for detecting the magnetic field, comprising a tapered acoustic waveguide having a base and a tapered end, an electrically-conductive wire rigidly coupled to the tapered end, and an electroacoustic transducer rigidly coupled to the base; and
a control and acquisition device coupled to the device for detecting the magnetic field comprising a generator configured to supply a pair of current pulses of opposite directions or a plurality of frequency-modulated current pulses into t electrically-conductive wire and an acquisition circuit configured to detect electrical signals supplied by the electroacoustic transducer or a generator configured to supply a pair of voltage pulses of opposite signs or a plurality of frequency-modulated voltage pulses controlling the electroacoustic transducer and an acquisition circuit configured to detect electrical signals supplied by the electrically-conductive wire.

According to an embodiment, the generator is configured to supply a plurality of pairs of current pulses of opposite directions into the electrically-conductive wire or a plurality of pairs of voltage pulses of opposite signs controlling the electroacoustic transducer.

According to an embodiment, the generator is configured to supply the pulses having maximum amplitudes in absolute value identical to better than within 2%.

According to an embodiment, the frequency modulation of the plurality of frequency-modulated current or voltage pulses is located within the bandwidth of the electroacoustic transducer.

According to an embodiment, the acquisition circuit is configured to determine the difference between the electrical signals supplied for the first pulse of the pair of pulses and the second pulse of the pair of pulses.

According to an embodiment, the control and acquisition device is configured to determine the time of transit of acoustic waves in the tapered acoustic waveguide between the base and the tapered end, the acquisition circuit being configured to acquire the electrical signals in a time window having its beginning relative to the first of the pulses depending on the transit time.

According to an embodiment, the electrically-conductive wire comprises first and second ends, the electroacoustic transducer comprises first and second electrodes, and the generator comprises first and second voltage sources. The first voltage source is coupled to the first end of the electrically-conductive wire or to the first electrode of the electroacoustic transducer.

According to an embodiment, the second voltage source is coupled to the second end of the electrically-conductive wire or to the second electrode of the electroacoustic transducer.

According to an embodiment, the generator further comprises a first transformer having a first primary winding coupled to the first source and a first secondary winding coupled to the first end of the electrically-conductive wire or to the first electrode of the electroacoustic transducer.

According to an embodiment, the second source is coupled to the first primary winding.

According to an embodiment, the generator further comprises a second transformer having a second primary winding coupled to the second source and a second secondary winding coupled to the first end of the electrically-conductive wire or to the first electrode of the electroacoustic transducer.

According to an embodiment, the generator further comprises resistors of different values and a switch configured to connect in series one of the resistors with the first end of the electrically-conductive wire or with the first electrode of the electroacoustic transducer.

According to an embodiment, the generator further comprises a gas discharge tube between the first source and the first end of the electrically-conductive wire or the first electrode of the electroacoustic transducer and a capacitor having a plate coupled to a node between the first source and the gas discharge tube.

According to an embodiment, the system further comprises a device for emitting electromagnetic radiation onto the gas discharge tube.

According to an embodiment, the electrically-conductive wire comprises a thinned portion rigidly coupled to the tapered end.

According to an embodiment, the tapered acoustic waveguide comprises two tapered acoustic waveguide halves made of an electrically-conductive material and each comprising a pointed end, the two tapered acoustic waveguide halves being distant from each other except for the two tips, which coincide.

According to an embodiment, the tapered acoustic waveguide further comprises an electrically-insulating block between the two tapered acoustic waveguide halves and the electroacoustic transducer.

### BRIEF DESCRIPTION OF THE DRAWINGS

These features and advantages, as well as others, will be described in detail in the following description of specific embodiments, which is provided by way of example and is not intended to be limiting, in connection with the accompanying drawings, in which:

FIG. 1 is a cross-section view, partial and simplified, of an embodiment of a magnetic field detection system comprising a probe and a control and acquisition device;

FIG. 2, FIG. 3, FIG. 4, and FIG. 5 are cross-section views, partial and simplified, of other embodiments of the probe of the detection system;

FIG. 6 is a perspective view, partial and simplified, of the end of the probe of FIG. 3;

FIGS. 7 and 8 are block diagrams of the detection system of FIG. 1 illustrating embodiments of the control and acquisition device of the detection system;

FIG. 9 shows timing diagrams of the measurement signal supplied by an amplifier of the detection system illustrating a thermoacoustic effect of the probe;

FIG. 10 shows timing diagrams of the measurement signal in the absence of a magnetic field and in the presence of magnetic fields having equal amplitudes and opposite directions;

FIG. 11 shows a timing diagram of a bipolar current pulse;

FIG. 12 is a timing diagram of the measurement signal supplied by the detection system for the measurement of a reflected acoustic wave:

FIG. 13 shows a curve of variation of the voltage due to the thermoacoustic effect and a curve of variation of the sensitivity of the detection system as a function of the intensity of current pulses;

FIGS. 14, 15, 16, and 17 are electrical diagrams of embodiments of a current pulse generator of the detection system of FIG. 7;

FIG. 18 is a perspective view, partial and simplified, of an embodiment of a conductive wire of the probe of the detection system having a thinned portion;

FIG. 19 is a perspective view, partial and simplified, of the conductive wire at an intermediate step of a method of manufacturing the conductive wire having a thinned portion;

FIG. 20 and FIG. 21 are cross-section views, partial and simplified, of embodiments of the probe of the detection system;

FIG. 22 shows timing diagrams of the measurement signal, respectively without processing and after the implementation of a method for compensating for the thermoacoustic effect;

FIG. 23 shows a timing diagram of the pulse response of a matched filter;

FIGS. 24, 25, and 26 show timing diagrams of measurement signals;

FIG. 27 is a timing diagram of pulse generator control signals;

FIG. 28 is an electrical diagram of an embodiment of a voltage pulse generator of the detection system of FIG. 8;

FIG. 29 shows a timing diagram of an amplified measurement signal;

FIG. 30 shows a curve of the Fourier transform of the amplified measurement signal of FIG. 29; and

FIG. 31 and FIG. 32 are electrical diagrams of other embodiments of the current pulse generator of the detection system of FIG. 7.

### DESCRIPTION OF EMBODIMENTS

The same elements have been designated by the same references in the various figures. In particular, structural and/or elements functional common to the different embodiments may have the same references and may have identical structural, dimensional and material properties.

For the sake of clarity, only those steps and elements that are useful for understanding the described embodiments have been shown and have been described in detail.

Unless otherwise specified, when reference is made to two elements being connected to each other, this means directly connected without any intermediate elements other than conductors, and when reference is made to two elements being coupled to each other, this means that these two elements may be connected or may be connected via one or more other elements.

In the following description, where reference is made to absolute position qualifiers, such as the terms “front”, “back”, “top”, “bottom”, “left”, “right”, etc., or relative position qualifiers, such as the terms “top”, “bottom”, “upper”, “lower”, etc., or orientation qualifiers, such as “horizontal”, “vertical”, etc., reference is made unless otherwise specified to a probe in a normal position of use.

Unless specified otherwise, the expressions “about”, “approximately”, “substantially”, and “in the order of” signify plus or minus 10% or 10°, preferably of plus or minus 5% or 5°. Further, it is here considered that the terms “insulating” and “conductive” respectively signify “electrically insulating” and “electrically conductive”.

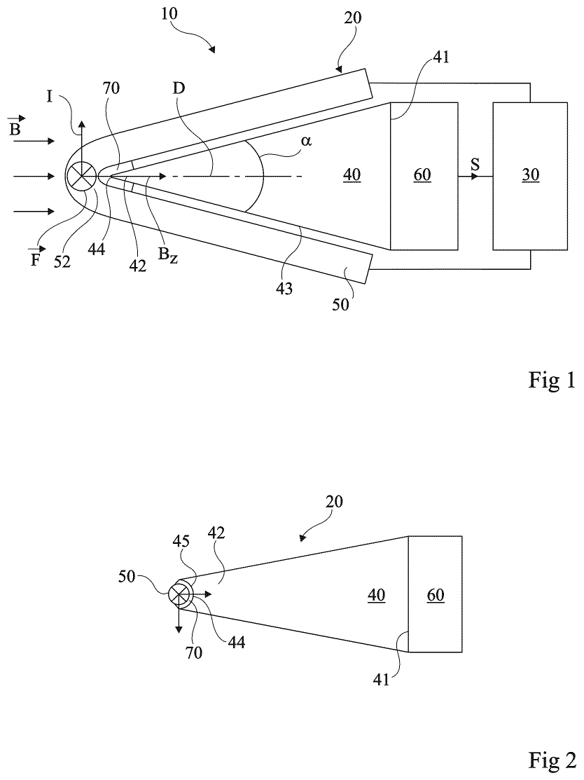

FIG. 1 is a cross-section view, partial and simplified, of an embodiment of a system 10 for detecting a component B_{z} of a magnetic field \vec{B}.

System 10 comprises a magnetic field detection device 20, referred to as probe hereafter, and a control and acquisition device 30 coupled to probe 20. Probe 20 comprises an acoustic waveguide 40, an electrically-conductive wire 50, and an electroacoustic transducer 60.

Acoustic waveguide 40 has a tapered shape along an axis D with a cross-section having a surface area decreasing from a base 41 to a tapered end 42, called tip hereafter, opposite to base 41. Acoustic waveguide 40 is referred to as tapered guide 40 hereafter. Conductive wire 50 extends along the side wall 43 of tapered guide 40 all the way to tip 42. According to an embodiment, conductive wire 50 is folded over tip 42 and secured to tip 42 by a bonding material 70.

According to an embodiment, tapered guide 40 has a general cone or truncated cone shape. Preferably, tapered guide 40 has rotational symmetry about axis D. According to another embodiment, tapered guide 40 has a general prismatic shape, in particular with a triangular base. At least in a plane containing axis D, tapered guide 40 has a triangular cross-section with an apex angle α smaller than 15°, preferably smaller than 10°, and more preferably smaller than 5°. When tapered guide 40 has a general cone or truncated cone shape, apex angle α corresponds to the apex angle of the cone. When tapered guide 40 has the general shape of a prism with a triangular base, apex angle α is the apex angle of the triangular base on the side of the tip 42 of tapered guide 40. Conductive wire 50 has a portion 52 covering the tip of tapered guide 40 through which the current flows substantially perpendicularly to the axis D of tapered guide 40.

In operation, the tip 42 of tapered guide 40 is placed at the location where magnetic field \vec{B} is present. System 10 enables to measure the component B_{z}, along the axis D of tapered guide 40, of magnetic field \vec{B}.

According to an embodiment, conductive wire 50 has a cylindrical cross-section. According to another embodiment, conductive wire 50 has a cross-section which is not cylindrical. In the case where conductive wire 50 has a cross-section which is not cylindrical, there is called diameter of conductive wire 50 the diameter of the disk of same surface area as the surface area of the cross-section of conductive wire 50. According to an embodiment, conductive wire 50 has a diameter varying from 10 μm to 200 μm, for example equal to approximately 40 μm. According to an embodiment, conductive wire 50 comprises a conductive core surrounded by an insulating sheath, for example an enameled wire. According to another embodiment, conductive wire 50 corresponds to a conductive track deposited on tapered guide 40.

According to an embodiment, the tip 42 of tapered guide 40 comprises a surface 44, referred to as bearing surface 44 hereafter, having the portion 52 of conductive wire 50 resting thereon.

According to an embodiment, bearing surface 44 is planar and perpendicular to the axis D of tapered guide 40. According to an embodiment, bearing surface 44 is inscribed within a disk. The diameter of the disk having support surface 44 inscribed therein is then referred to as the diameter of bearing surface 44. According to an embodiment, bearing surface 44 is not planar. In this case, the diameter of bearing surface 44 is defined as the diameter of the disk having bearing surface 44 inscribed therein when it is viewed along axis D.

According to an embodiment, bearing surface 44 has a diameter in the range from the diameter of conductive wire 50 to five times the diameter of conductive wire 50, for example from twice to five times the diameter of conductive wire 50. According to an embodiment, bearing surface 44 has a diameter in the range from twice to five times the diameter of conductive wire 50. According to an embodiment, bearing surface 44 has a diameter equal to the diameter of conductive wire 50. The periphery of bearing surface 44 then forms a bearing surface protecting conductive wire 50. The closer the diameter of conductive wire 50 is to the diameter of bearing surface 44, the less the propagation effects in the vicinity of tip 42 are felt. As an example, for a conductive wire 50 having a diameter equal to 40 μm, the diameter of bearing surface 44 may be close to 100 μm.

Further, to avoid crushing conductive wire 50 during measurements, a notch having a depth equal to the diameter of conductive wire 50 may be made in the plane of bearing surface 44 so as to embed conductive wire 50 in tip 42.

FIG. 2, FIG. 3, FIG. 4, and FIG. 5 are cross-section views, partial and simplified, of other embodiments of probe 20. The cross-section plane of FIGS. 2 to 5 contains the axis D of tapered guide 40 and is perpendicular to the cross-section plane of FIG. 1.

In the embodiment illustrated in FIG. 2, the diameter of bearing surface 44 is equal to the diameter of conductive wire 50, and bearing surface 44 comprises a notch 45 having conductive wire 50 embedded therein. This embodiment is adapted, in particular, for low-amplitude magnetic fields. Bonding material 70 may be distributed in notch 45. The portion 52 of conductive wire 50 resting on bearing surface 44 extends substantially linearly along an axis perpendicular to the axis D of tapered guide 40. Preferably, the length of the linear portion 52 of conductive wire 50 does not exceed half a wavelength of the phase velocity of the transverse waves, that is, typically less than 0.5 mm at 1 MHz and 0.1 mm at 5 MHz. The embodiment illustrated in FIG. 2 allows detection of magnetic field \vec{B} with the best spatial resolution as compared with the embodiments illustrated in FIGS. 3 to 5.

In the embodiment illustrated in FIG. 3, bearing surface 44 is planar and the diameter of bearing surface 44 is equal to approximately 3 times the diameter of conductive wire 50. Conductive wire 50 is laid flat on bearing surface 44 and is protected by bonding material 70.

In the embodiment illustrated in FIG. 4, the diameter of bearing surface 44 is equal to approximately 3 times the diameter of conductive wire 50, and bearing surface 44 comprises a notch 45 having conductive wire 50 embedded therein.

In the embodiment illustrated in FIG. 5, tapered guide 40 comprises a through opening 46 in tip 42 near the end of tip 42, for example at a distance from the end of tip 42 ranging from one time to twice the diameter of conductive wire 50. The diameter of through opening 46 is slightly larger than the diameter of conductive wire 50, and conductive wire 50 extends through opening 46. Conductive wire 50 is rigidly coupled to tapered guide 40 by bonding material 70 or by compression and deformation of the end of tip 42, which slightly pinches conductive wire 50.

The embodiments illustrated in FIGS. 3, 4, and 5 are advantageously more robust than the embodiment illustrated in FIG. 2. The embodiments illustrated in FIGS. 3, 4, and 5 are particularly suitable for applications in which it is envisaged to be able to place probe 20 into contact with a magnetized surface. Further, the risk of crushing of conductive wire 50 in the embodiments illustrated in FIGS. 4 and 5 is decreased as compared with the embodiments illustrated in FIGS. 2 and 3.

The larger the diameter of bearing surface 44, the less disturbance there is to the measurement when tip 42 comes into contact with a hard surface. Indeed, the radiation impedance of tip 42 drops considerably as the end of tip 42 is approached. Its blocking by a hard surface could limit the amplitude of the mechanical pulse generated by the Lorentz force, which is applied to a small volume of material, laterally free. This could alter the measurement by decreasing the amplitude of the signal. Further, the contact of tip 42 with a solid medium may generate ultrasonic waves in the medium, which may return to tip 42 and alter the measurement.

Advantageously, the lateral bulk of the tip 42 of probe 20 is at least ten times smaller than the lateral bulk of commercially-available Hall effect probes.

According to an operating mode of system 10, called direct operating mode hereafter, control and acquisition device 30 is configured to control electroacoustic transducer 60 for the generation of an acoustic wave in tapered guide 40. In direct operating mode, tapered guide 40 enables to propagate the ultrasonic wave from base 41 to tip 42. The ultrasonic wave causes a bending of tip 42. The displacement of tip 42, and thus of conductive wire 50 in magnetic field \vec{B}, causes the appearing of an electromotive force EMF in conductive wire 50. Electromotive force EMF is proportional to the B_{z} component of the magnetic field \vec{B} to be measured. Control and acquisition device 30 is configured to measure the electromotive force EMF at the ends of conductive wire 50 and to deduce therefrom the B_{z} component of magnetic field \vec{B} and the polarization of the magnetic field \vec{B} present at the tip 42 of tapered guide 40.

In the direct operating mode, the Lorentz force applied to the portion 52 of conductive wire 50 located on the tip 42 of tapered guide 40 has a maximum amplitude Fₘₐₓ given by the following relation:

$${F}_{ma x} = Q {v}_{ma x} {B}_{z} \qquad [ Math 1 ]$$

where Q is the space charge located at the end of the conductive wire 50, and Vₘₐₓ is the maximum beat frequency of the tip 52 of tapered cone 40. This results in a voltage V_{N} at the ends of the conductive wire 50.

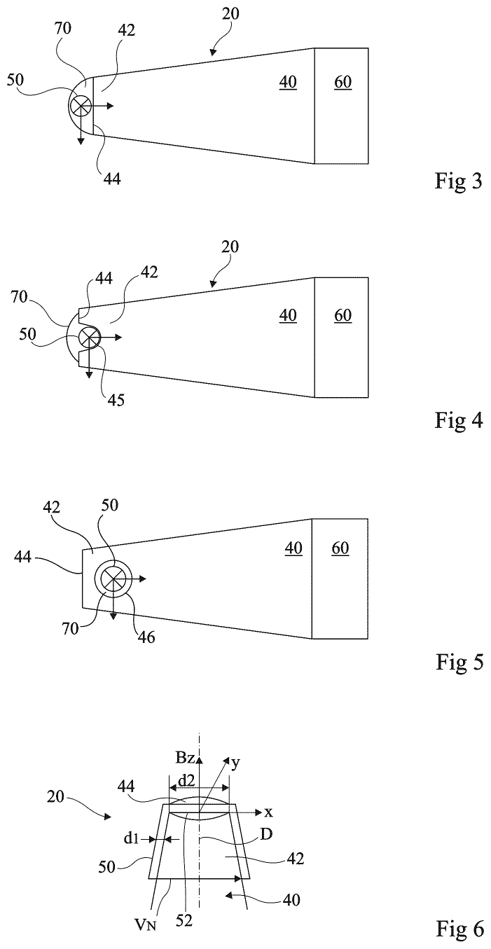

FIG. 6 is a perspective view, partial and simplified, of the end of the probe 20 of FIG. 3, illustrating an example of determination of space charge Q.

Conductive wire 50 has a diameter d₁ and tops the bearing surface 44 of diameter d2 at the tip 42 of tapered guide 40 of axis D. Conductive wire 50 corresponds to a given volume of space charges vibrating in the Y direction.

The voltage V_{N} across conductive wire 50 is given by the following relation, obtained by making explicit the fact that the Lorentz force is balanced by the Coulomb force:

$${V}_{N} = ( {d}_{2} + 2 {d}_{1} ) {v}_{ma x} {B}_{z} \qquad [ Math 2 ]$$

According to an operating mode of system 10, called inverse operating mode or reciprocal operating mode hereafter, control and acquisition device 30 is configured to supply a current pulse into conductive wire 50. The current pulse has an intensity I and a duration Δt, also called pulse width hereafter. In the presence of magnetic field \vec{B} at the tip 42 of tapered guide 40, there appears in the portion of conductive wire 50 located at the tip 42 of tapered guide 40 a Lorentz force F having its amplitude F defined by the following relation:

$$F = I Δ {tv}_{e} {B}_{z} \qquad [ Math 3 ]$$

where vₑ is the velocity of electrons in conductive wire 50.

In the reciprocal operating mode, tapered guide 40 enables to convert Lorentz force \vec{F} into a pulsed ultrasonic bending wave which remains broadband during its propagation through tapered guide 40. The amplitude of the ultrasonic bending wave is in particular proportional to the B_{z} component of the magnetic field \vec{B} to be measured, to the intensity I of the current pulse, and to the duration Δt of the current pulse. The bending wave is polarized in the direction of the vector product \vec{I}\hat{ }\vec{B} perpendicularly to the plane of FIG. 1 defined by axis D and the tangent to conductive wire 50 defining the current vector \vec{I} at the location where conductive wire 50 is rigidly secured to tip 42. Due to its generally tapered shape with a small apex angle, tapered guide 40 favors the propagation of an acoustic bending mode generated at the end of tip 42 all the way to base 41. The intrinsic impedance of the material forming tapered guide 40 is equal to the product of the fundamental velocity of a transverse wave in the material by the density of the material. The mechanical radiation impedance of the tip 42 of tapered guide 40 is defined as the product of the phase velocity of an acoustic wave at the location of the coupling by the density of the material forming tapered guide 40. The mechanical radiation impedance is particularly low, typically from 3 to 4 times lower than the intrinsic impedance of the material. This feature is advantageously adapted to an efficient transfer of the Lorentz force appearing in conductive wire 50 rigidly coupled to tip 42 by bonding. The acoustic wave reaches electroacoustic transducer 60, which converts it into an analog electrical measurement signal S, for example a voltage. Control and acquisition device 30 is configured to measure the electrical signal S supplied by electroacoustic transducer 60 and to deduce therefrom the amplitude of the B_{z} component of magnetic field \vec{B} and the polarization of the magnetic field \vec{B} present at the tip 42 of tapered guide 40.

According to an embodiment, the intensity I of the current pulse is preferably as high as possible, in practice between 1 A and 100 A, preferably approximately 50 A. According to an embodiment, the duration Δt of the current pulse is as short as possible, for example between 1 ns and 500 ns, preferably approximately 10 ns. In the case where the magnetic field to be measured corresponds to a magnetic pulse, the duration Δt of the current pulse is shorter than the duration of the magnetic pulse to be measured. In the case where the magnetic field to be measured corresponds to a sinusoidal magnetic field, the duration Δt of the current pulse is shorter than the half-period of the sinusoidal magnetic field to be measured. Generally, in the case where the magnetic field to be measured varies over time, the duration Δt of the current pulse is shorter than the half-period corresponding to the maximum frequency of variation of the magnetic field.

In reciprocal mode, tapered guide 40 advantageously introduces an acoustic propagation delay, from 1 us to 100 μs, between the electrical pulse present at the tip 42 of tapered guide 40 and the delivery of electrical signal S by electroacoustic transducer 60. This enables to prevent interference with the receiver amplifier of control and detection device 30 by direct air coupling between the electrical pulse and the receiving electronics.

Conductive wire 50, for example made of copper, has a density μ_{Cu} and a cross-sectional area S_{Cu}. Tapered guide 40, for example made of aluminum, has a density μ_{Al} and a cross-sectional area S_{Al}, locally considered as a cylinder of height λ/2 where λ is the wavelength of the bending wave at the end of tip 42. The total mass M of material set in motion by the Lorentz force is approximately given by the following relation:

$$M = {μ}_{Cu} {S}_{Cu} ( {d}_{2} + 2 {d}_{1} ) + {μ}_{Al} {S}_{Al} \frac{λ}{2} \qquad [ Math 4 ]$$

The maximum velocity vₘₐₓ of the vibration amplitude generated in tip 42 can be approximated by the following relation:

$${v}_{m ax} = \frac{( {d}_{2} + 2 {d}_{1} ) \cdot I \cdot Δ t \cdot {B}_{z}}{{μ}_{Cu} {S}_{Cu} ( {d}_{2} + 2 {d}_{1} ) + {μ}_{Al} {S}_{Al} \frac{λ}{2}} \qquad [ Math 5 ]$$

This bending wave propagates in tapered guide 40, the characteristic gain of which is g(z) where z is a negative abscissa along the axis D of tapered guide 40, with g(0) corresponding to the gain at the end of tip 42 and g(H) corresponding to the gain at the base 41 of tapered guide 40 of height H measured along axis D.

When tapered guide 40 corresponds to a cone, the empirical gain g of a mechanical vibration of amplitude u(x) measured on axis D of the cone, for a bending mode propagating along the cone, can be approximated by the following relation:

$$g ( x , 0 ) = \frac{u ( x )}{{u}_{ref} ( {z}_{ref} )} = \frac{{G}_{C} H}{H + K ( 1 - {G}_{C} ) x} \qquad [ Math 6 ]$$

where G_{C} corresponds to the gain of the cone measured at the end of tip 42 relative to a reference vibration amplitude measured at an abscissa z_{ref}, measured along axis D, equal to −H/K. Parameter K is a constant characteristic of the variation speed of the mechanical gain in the vicinity of the end of tip 42. As an example, for an aluminum cone having a height H equal to 84 mm, constant K is equal to 11.2, gain G_{C} is equal to 12.4, and abscissa z_{ref} is equal to 7.5 mm. At the base of the cone, gain g(−H, 0) is equal to 130, that is, the cone offers a transverse mechanical gain by approximately a factor 130.

When the bending wave reaches the outer surface of transducer 60, the mechanical vibration vi corresponding to a mechanical displacement u₁ is transformed under high electrical load impedance (and in the case where the rear surface of transducer 60 is either blocked or much weaker) into an electrical voltage V₃ across transducer 60, which can be approximately expressed by the following relation:

$${V}_{3} = h \cdot {u}_{1} = \frac{h}{ω} {V}_{1} \qquad [ Math 7 ]$$

where h is the piezoelectric constant and ω is the angular pulse, which is equal to 2πf, where f is the oscillation frequency of the bending wave. Expressing the fact that mechanical vibration v₁ is simply the mechanical vibration v at the end of tip 42 divided by the gain of the cone, the following relation is obtained:

$${V}_{3} = \frac{h}{ω \cdot g ( - H )} \cdot \frac{( {d}_{2} + 2 {d}_{1} ) \cdot I \cdot Δ t \cdot {B}_{z}}{{ρ}_{Cu} {S}_{Cu} ( {d}_{2} + 2 {d}_{1} ) + {ρ}_{Al} {S}_{Al} \frac{λ}{2}} \qquad [ Math 8 ]$$

Relations Math 2 and Math 8 are two formulas modeling the output voltage of probe 20 as a function of its operating parameters. Relation Math 2 corresponds to the case where transducer 60 is active and generates, after a propagation delay Tr in tapered guide 40, an amplified beat of tip 42 and an electrical voltage V_{N} across conductive wire 50 in the presence of magnetic field B_{z}, and relation Math 8 corresponds to a case where a current pulse I for sampling magnetic field B_{z} generates a bending which transforms into a wave that propagates all the way to the base 41 of tapered guide 40 and is converted into an electrical voltage V₃ across transducer 60.

According to the principle of reciprocity, these two formulas provide the same signal shape, provided for the phenomena to be linear. However, a difference in input and output impedances between the direct operating mode, where transducer 60 is the transmitter, and the reciprocal operating mode, where the measurement pulse current is at low source impedance, is advantageous for the reciprocal operating mode. Indeed, with a tapered guide 40 corresponding to a truncated aluminum cone with a height H equal to 85 mm and a base diameter equal to 7 mm, truncated with a bearing surface 44 having a diameter d₂ equal to 0.2 mm, and with an enameled copper conductive wire 50 having a diameter d₁ equal to 100 μm, there is obtained in the reciprocal operating mode, by using a 66-dB (2,000 linear) gain amplifier, a sensitivity V₃ equal to 9I with I expressed in amperes, that is, practically 630 V/T for a 70-A current, while in the direct operating mode, V_{N} equal to 10 mV/T for a 300-V voltage pulse is obtained, which leads to a 20V/T sensitivity after a 66-dB gain.

In reciprocal operating mode, for voltage V₃ to be significant, sampling pulse current I thus needs to be as strong as possible. However, there exists a limit due to an effect described hereafter, called thermoacoustic effect, which introduces non-linearity.

According to an embodiment, conductive wire 50 comprises at least one core made of an electrically-conductive material, optionally surrounded by an electrically-insulating sheath. According to an embodiment, the conductive material is selected from among copper, a material having an electron mobility greater than 30 cm²/V/s (in particular gold, silver, or a semiconductor material such as graphene), or a mixture of at least two of these compounds. The nature of the conductor forming conductive wire 50 is important, be it for a direct or reciprocal operation, when the sensitivity of probe 20 to low-intensity magnetic fields is desired to be increased. By default, an enameled copper conductive wire 50 may be used for magnetic fields ranging from a few milliteslas to several tens of teslas. However, for applications requiring a high sensitivity to low-intensity magnetic fields, typically when they are comparable to or lower than one millitesla or the magnetic field of the Earth, materials having a higher electron mobility than that of copper (which is equal to 30 cm²/V/s) may be used, such as gold (43 cm²/V/s), silver (68 cm²/V/s) or semiconductor materials such as graphene. A copper wire coated with a layer of graphene, having an electron mobility that can reach 200,000 cm²/V/s, may also be selected. The electrical voltage which appears across conductive wire 50 in direct mode is thus increased by the higher electron mobility of the material forming conductive wire 50, and probe 20 generates a usable signal and an improved signal-to-noise ratio at weaker magnetic fields with respect to the case where a simple enameled copper conductive wire 50 would have been used.

According to an embodiment, tapered guide 40 is made of a solid non-magnetic material, in particular a material selected from the group comprising glass, silicon, ceramic, alumina-zirconia composites, non-magnetic metals (in particular aluminum, copper, or titanium), austenitic steel, and non-magnetic metal alloys, in particular alloys based on aluminum, copper, and/or titanium.

Tapered guide 40 enables, due to its tapered geometric shape, to advantageously form a thermal buffer between the measurement area at tip 42 and a receiving area on electroacoustic transducer 60. The measurement area may then be taken to a high temperature of several hundred degrees Celsius, while the receiving area may be subjected to a lower temperature compatible with the temperature range tolerated by electroacoustic transducer 60.

Bonding material 70 may be a cyanoacrylate resin, or an epoxy resin, or a polyimide resin, or a ceramic resin, or fused glass, or a sintered powder, or enamel coating conductive wire 50. According to an embodiment, bonding material 70 is adapted to withstanding high temperatures, for example up to 1,000° C., or up to the lowest of the melting temperatures of the tip 42 of tapered guide 40 and the melting temperature of conductive wire 50. Bonding material 70 is, for example, the high-temperature adhesive marketed under the name Ceramabond by Aremco.

In the reciprocal operating mode, acoustic transducer 60 is configured to receive an acoustic wave and supply an analog electrical signal, for example a voltage or a current, called measurement signal hereafter. The amplitude of the measurement signal depends on the amplitude of the acoustic wave, and is preferably proportional to the amplitude of the acoustic wave. In the reciprocal operating mode, acoustic transducer 60 receives a packet and delivers an electrical measurement signal comprising at least one peak, and generally a plurality of positive and negative peaks. In the direct operating mode, acoustic transducer 60 is configured to receive an analog electrical signal, for example a voltage or a current, called control signal hereafter, and to supply an acoustic wave. The amplitude of the acoustic wave depends on the amplitude of the control signal, and is preferably proportional to the amplitude of the control signal. Acoustic transducer 60 may be a transverse wave acoustic transducer. According to an embodiment, acoustic transducer 60 is a piezoelectric transducer or an electromagnetic acoustic transducer. Transducer 60 is, for example, the piezoelectric transducer marketed by Evident (formerly Olympus, formerly Panametrics, Waltham, MA, USA) under trade name V153, which can have a center frequency around 1 MHz.

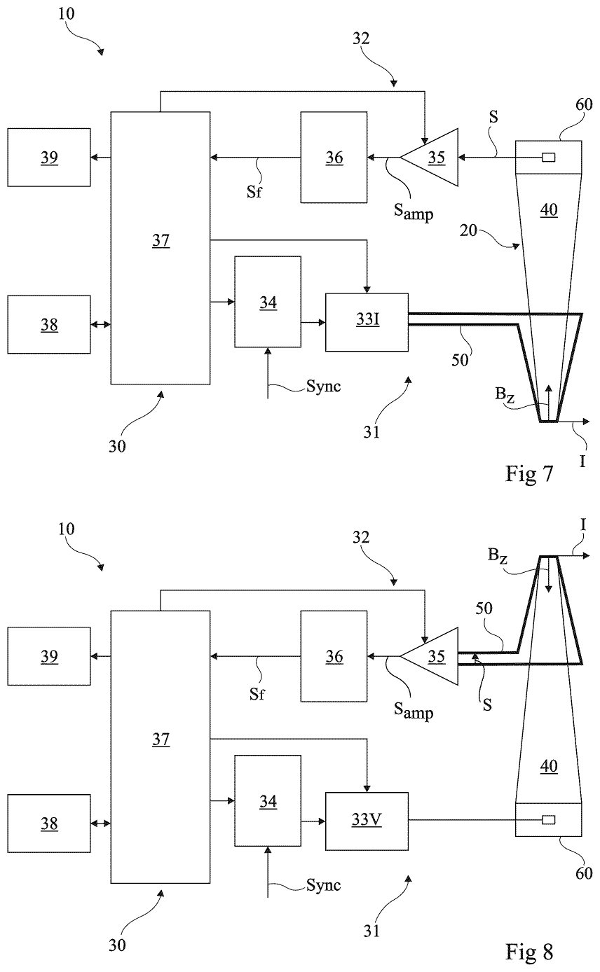

FIG. 7 shows a block diagram of detection system 10 illustrating an embodiment of control and acquisition device 30 for the implementation of the reciprocal operating mode. According to an embodiment, electroacoustic transducer 60 is a piezoelectric transducer.

Control and acquisition device 30 comprises, in particular, a control chain 31 and an acquisition chain 32. Control chain 31 comprises:
a generator 33I of current pulses in conductive wire 50 coupled to both ends of conductive wire 50; and
a module 34 for controlling current pulse generator 33I receiving a synchronization signal Sync.

Acquisition chain 32 comprises:
a programmable amplifier 35 receiving the analog measurement signal S supplied by electroacoustic transducer 60, equal for example to the voltage across electroacoustic transducer 60, and delivering an amplified analog measurement signal Sₐₘₚ substantially equal to the measurement signal S multiplied by an amplification gain G1; and
a processing module 36 receiving the amplified measurement signal Sₐₘₚ delivered by amplifier 35 and delivering a measurement signal Sf equal to the amplified measurement signal Sₐₘₚ to which various processes have been applied, for example a filtering.

Control and acquisition device 30 further comprises:
a microcontroller 37 coupled to amplifier 35, to processing module 36, to control module 34, and to generator 331;
a computer 38 coupled to microcontroller 37; and
a man-machine interface 39 coupled to microcontroller 37, and/or to computer 38 and comprising, in particular, a display screen.

As a variant, control module 34 and/or processing module 36 may be incorporated in microcontroller 37. Acquisition chain 32 may comprise an oscilloscope, for example the oscilloscope marketed under trade name Pico 5242A by Pico Technology.

The control and acquisition device 30 illustrated in FIG. 7 is configured to generate a current pulse in conductive wire 50 with an intensity I and a duration Δt, and possibly occurring after a delay Td following a pulse of the synchronization signal Sync in the case of a synchronous measurement.

Computer 38 is configured to exchange signals with microcontroller 37, for example via a UART (Universal Asynchronous Receiver-Transmitter) port, in particular the values of delay Td, of duration Δt, of intensity I, and of the gain value G1 of programmable amplifier 35.

According to an embodiment, the gain value G1 of programmable amplifier 35 is determined from the amplitude B_{z} of the magnetic field determined during the previous measurement. The lower the amplitude B_{z} determined during the previous measurement, the greater the gain value G1, for example according to stages corresponding to measurement ranges of amplitude B_{z}.

According to an embodiment, the triggering of the measurement process is performed from synchronization signal Sync if the measurement is synchronous. According to another embodiment, the triggering of the measurement process is performed automatically and periodically with a measurement period defined by the user if the measurement is asynchronous. In this case, the measurement period is preferably longer than the decay time of the acoustic pulse propagating in tapered guide 40 due to the previous current pulse.

According to an embodiment, generator 33I applies a current pulse of intensity I in the conductive wire 50 coupled to the tip 42 of tapered guide 40 with a delay Td and a duration Δt defined in control module 34. In the presence of magnetic field \vec{B}, an ultrasonic acoustic wave, having a peak amplitude proportional to the B_{z} component, progresses from the tip 42 to the base 41 of tapered guide 40. The acoustic wave is converted into an electrical measurement signal S by the acoustic transducer 60 coupled base 41, and the electrical measurement signal S is amplified by programmable amplifier 35 to provide the amplified measurement signal Sₐₘₚ.

According to an embodiment, processing module 36 is configured to detect the peak amplitude of amplified measurement signal Sₐₘₚ and to deliver an analog value of the detected peak amplitude to microcontroller 37. According to an embodiment, processing module 36 is further configured to determine a binary value Polar I/O representative of the positive or negative sign of the first pulse of the amplified measurement signal Sₐₘₚ. Indeed, the phase of the acoustic wave changes by 180° depending on whether the polarization of the B_{z} component is directed in one direction or the opposite direction. Microcontroller 37 may further comprise an analog-to-digital converter adapted to receiving the analog value of the detected peak amplitude and to supplying a digital signal of the peak amplitude.

According to an embodiment, microcontroller 37 is configured to directly receive amplified measurement signal Sₐₘₚ and to perform a sampling of amplified measurement signal Sₐₘₚ, for example over a depth of from 10 to 16 bits and at a rate of from 5 to 12 megasamples per second over a time window from 1 us to 100 μs. According to an embodiment, microcontroller 37 is configured to perform an interpolation of the measurement points in order to finely reconstruct the amplified measurement signal and to obtain a precise value for the peak amplitude and the phase of the amplified measurement signal.

According to another embodiment, microcontroller 37 is configured to determine the Fourier transform of amplified measurement signal Sₐₘₚ. Preferably, the Fourier transform is determined from the time trace of amplified measurement signal Sₐₘₚ including the peaks of amplified measurement signal Sₐₘₚ and excluding the parasitic coupling of the current or voltage pulse so that there only remain in the time trace peaks due to the reception of the acoustic wave packet by transducer 60 with a zero measurement signal before its arrival and after its arrival.

According to an embodiment, amplified measurement signal Sₐₘₚ is processed so that its values are zero after the fourth or fifth zero crossing of amplified measurement signal Sₐₘₚ, which corresponds to the time when most of the acoustic wave packet has been received by transducer 60 and the end portion of the acoustic wave packet is entered. The spectral line of maximum amplitude of the obtained spectrum corresponds to the center frequency of the acoustic wave packet. The amplitude of the spectral line is representative of the maximum amplitude value of amplified measurement signal Sₐₘₚ.

The determination of the peak amplitude of amplified measurement signal Sₐₘₚ from the Fourier transform of amplified measurement signal Sₐₘₚ rather than directly from amplified measurement signal Sₐₘₚ is more precise and more independent of the analog noise existing in amplified measurement signal Sₐₘₚ. This enables to access weak magnetic fields close to the magnetic field of the Earth. In these extreme cases, the sensitivity is increased by replacing the current pulse with a pulse train, comprising, for example, from 2 to 10 pulses and preferably 4 equidistant current pulses, with a carrier centered on the center frequency of electromechanical transducer 60. Further, advantageously, the Fourier transform of amplified measurement signal Sₐₘₚ is independent of the time of propagation of the acoustic waves in tapered guide 40. The effect of a change in temperature of tapered guide 40 then results in an advance or a delay in the arrival of the acoustic wave packet in transducer 60, that is, a mere phase change in the Fourier space.

Microcontroller 37 is configured to determine the value of field B_{z} by multiplying the peak value by a calibration coefficient. The value of magnetic field B_{z} and its polarization (north, south) are displayed on display 39 in a selected measurement unit or transmitted to computer 38 for further processing.

According to an embodiment, control and acquisition device 30 may drive one, two, or more than two probes 20 based on the same synchronization signal Sync, where each of probes 20 may be excited with a delay Td identical or different with respect to the other probes 20 so that the spatial and temporal sampling can be multiplied by the number of probes 20 used. If a plurality of probes 20 are excited with slightly different delays Td and arranged at virtually the same location of a magnetic source relatively extended in space but oscillating very rapidly, the number of magnetic field sampling points can be multiplied by the number of probes 20 used.

FIG. 8 shows a block diagram of detection system 10 illustrating an embodiment of control and acquisition device 30 for the implementation of the direct operating mode. The control and acquisition device 30 shown in FIG. 8 comprises the same elements as the control and acquisition device 30 shown in FIG. 7, with the difference that the analog measurement signal S received by amplifier 35 corresponds to the voltage across conductive wire 50 and that current pulse generator 33I is replaced by a generator 33V of voltage pulses supplied to transducer 60.

A disadvantage during the implementation of the reciprocal operating mode is related to the occurrence of the thermoacoustic effect corresponding to the expansion of conductive wire 50 when the intensity I of the current flowing therethrough generates a significant Joule effect. The pulse of current I generates a heat pulse which is transformed, under adiabatic conditions, into a pulsed thermal expansion.

A first test was carried out. In the first test, the probe 20 shown in FIG. 1 is used and system 10 is used in the reciprocal operating mode. The height H of tapered guide 40, measured along its axis of revolution D, is 82 mm, and the diameter at base 41 is 7 mm. The apex angle α at the top of tapered guide 40 is 4.6°. Conductive wire 50 has a diameter d₁ equal to 40 μm. Tapered guide 40 is made of aluminum and conductive wire 50 is an enameled copper wire bonded with cyanoacrylate resin to the bearing surface 44 of tapered guide 40. Electroacoustic transducer 60 is the broadband piezoelectric transverse wave transducer marketed by Evident Technologies (Waltham, MA, USA) under trade name V153, centered on 1 MHz. The amplification gain of the programmable amplifier is equal to 48 dB. For the first test, probe 20 is used in reciprocal mode and the current pulse transiting through conductive wire 50 has a duration Δt equal to 270 ns and an intensity I equal to 30 A.

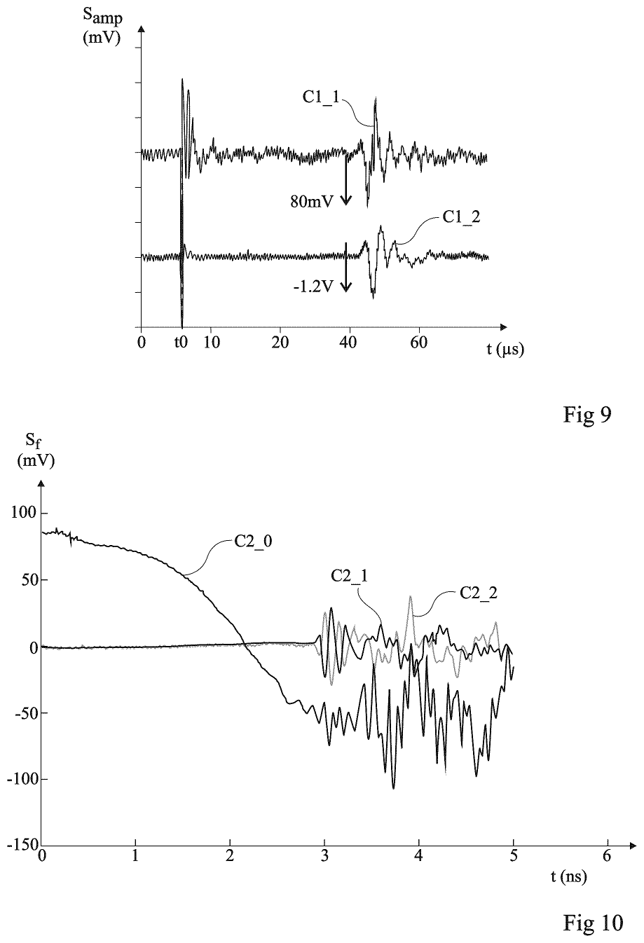

FIG. 9 shows timing diagrams C1_1 and C1_2 of the amplified measurement signal Sₐₘₚ provided by the amplifier 35 of detection system 10 for the first test. The y-axis scale is 50 mV per division for curve C1_1 and 5 V per division for curve C1_2. Curve C1_1 is obtained for a zero magnetic field and curve C1_2 is obtained for a magnetic field with a 480-mT amplitude. Time to corresponds to the sending of synchronization signal Sync for the control of current pulse generator 331. Amplified measurement signal Sₐₘₚ reaches 80 mV peak in the absence of a magnetic field and is only due to the thermoacoustic effect. The amplified measurement signal Sₐₘₚ in the presence of the magnetic field reaches a 1.2-V peak, that is, fifteen times greater than the amplified measurement signal Sₐₘₚ in the absence of the magnetic field. In the absence of a magnetic field, the current pulse may thus generate in tapered guide 40, alone, a parasitic acoustic wave.

The following formula gives the expected expansion of a conductive wire 50 having a cross-sectional area S_{Cu} and a length LG, an electrical resistivity ρ, undergoing a Joule effect during a pulse width Δt which corresponds to a dissipated energy ΔQ. By using the specific heat capacity Cp of copper conductive wire 50 of density u_{Cu}, the temperature increase ΔT in the conductive wire can be deduced and, knowing the thermal expansion coefficient β, the increase in free length of the wire ΔLG under adiabatic conditions can be deduced:

$$Δ Q = \frac{ϱ \cdot W \cdot {I}^{2} \cdot Δ t}{{S}_{Cu}} \qquad [ Math 9 ]$$

$$Δ T = \frac{ϱ \cdot {I}^{2} \cdot Δ t}{{S}_{C u}^{2} \cdot {ρ}_{C u} \cdot Cp}$$

$$Δ LG = \frac{β \cdot W \cdot ϱ \cdot {I}^{2} \cdot Δ t}{{S}_{C u}^{2} \cdot {ρ}_{C u} \cdot Cp}$$

For copper, the thermal expansion coefficient β is equal to 17*10⁻⁶/° C., the electrical resistivity ρ is equal to 1.66*10⁻⁸ Ω·m, the density u_{Cu} is equal to 8, 920 kg/m³, and the specific heat capacity Cp is equal to 315 J/kg/K. By selecting a length LG equal to 2 cm, current I equal to 60 A, a duration Δt equal to 0.5 μs, and a cross-sectional area S_{Cu} equal to 0.75*10⁻⁸ m², then the dissipated energy ΔQ is equal to 0.8 μJ/pulse, the temperature increase ΔT is equal to 0.2° C./pulse, and the increase in free length of the wire ΔLG is equal to 64 nm and the maximum speed vₘₐₓ of the vibration amplitude generated in tip 42 is equal to ΔW*Δt, that is, 0.12 m/s.

As can be seen, this parasitic signal varies inversely with the square of the diameter of conductive wire 50, proportionally to the square of pulse current I, and linearly with the decrease in pulse width Δt, because heat cannot be dissipated during the pulse, which makes the process adiabatic. In practice, between a conductive wire 50 having a diameter d₁ equal to 40 μm and a conductive wire 50 having a diameter d₁ equal to 100 μm, if the current pulse I is decreased from 60 A to 20 A, the thermoacoustic effect is decreased by a factor 56. Also knowing that the average current should not exceed 4 A/mm² in a section of conductive wire 50, it is verified that at a firing rate of 1,000 pulses/s, the average current remains at an acceptable level of 2.5 A/mm². Finally, if conductive wire 50 is closely coupled to the tip 42 of tapered guide 40, the process is no longer adiabatic, and heat can be more efficiently dissipated towards tapered guide 40 and its long-term thermal expansion is decreased, which is advantageous to prevent for conductive wire 50 to detach.

It is necessary to remove this parasitic acoustic wave to be able to measure weak magnetic fields, typically lower than 100 μT. This is achieved by implementing a method of compensation for the thermoacoustic effect and/or by providing a structure decreasing the thermoacoustic effect.

According to an embodiment, the compensation method comprises the measurement of a compensation signal which corresponds to the amplified measurement signal Sₐₘₚ obtained in the absence of a magnetic field, for example by placing probe 20 in a zero Gauss cavity. During the performing of a magnetic field measurement, the amplified and processed measurement signal S_{f} corresponds to the difference between amplified measurement signal Sₐₘₚ and the compensation signal.

A second test was performed. In the second test, the probe 20 of the first test is used. The amplification gain of amplifier 35 is equal to 66 dB. For the second test, probe 20 is used in the reciprocal operating mode and the current pulse I transiting through conductive wire 50 has an intensity equal to 8 A.

FIG. 10 shows timing diagrams C2_0, C2_1, and C2_2 of the amplified and filtered measurement signal S_{f} obtained for the second test. Curve C2_0 is obtained in the presence of a magnetic field having an amplitude equal to −1.7 mT in the absence of compensation. Curve C2_1 is obtained in the presence of a magnetic field having an amplitude equal to 1.7 mT, the amplified and filtered measurement signal S_{f} being equal to the difference between amplified measurement signal Sₐₘₚ and the compensation signal. Curve C2_2 is obtained in the presence of a magnetic field having an amplitude equal to −1.7 mT, amplified and filtered measurement signal S_{f} being equal to the difference between amplified measurement signal Sₐₘₚ and the compensation signal. Curves C2_0, C2_1, and C2_2 are obtained by averaging 1,000 acquisitions.

A disadvantage of the embodiment of the above-described compensation method is that if the temperature changes, there appears a shift of the time of transit in tapered guide 40 by a few nanoseconds/° C. and the compensation signal needs to be updated regularly. In this embodiment, the highest currents do not provide the best detectivity because high pulse currents create a strong local temperature increase, which then generates slow drifts in the time of transit inside tapered guide 40.

Another embodiment of a compensation method comprises the supply of current pulses through conductive wire 50 by alternating the direction of the current flowing through conductive wire 50 in two successive acquisitions.

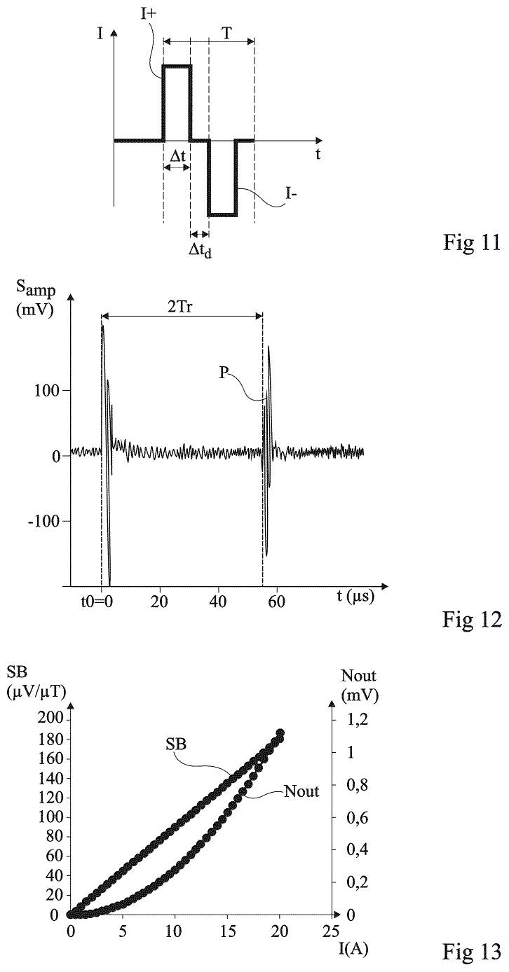

FIG. 11 shows a timing diagram of the current I flowing through conductive wire 50 for the performing of a magnetic field measurement in the reciprocal operating mode. Current I successively comprises a first current pulse I+ and a second current pulse I− transiting in conductive wire 50 in opposite directions. The combination of the two pulses I+ and I− is called bipolar pulse hereafter. In FIG. 11, current pulses I+ and I− are each square shaped. However, current pulses I+ and I− may have a different shape, for example a triangular or sinusoidal shape. There is called T the period of the bipolar pulse, which corresponds to the time between the rising edge of the first pulse I+ and the rising edge of the first pulse I+ of the next bipolar pulse. There is further called Δt the duration of the first pulse I+, which is equal to the duration of the second pulse I−. There is further called Δ_{d} the duration between the falling edge of the first pulse I+ and the rising edge of the second pulse I−.

The two current pulses I+ and I− of opposite directions create corresponding opposite Lorentz forces and also opposite analog measurement signals S, except for the component due to the thermoacoustic effect, which varies according to the square of the current intensity and inversely with the square of the cross-sectional area of conductive wire 50. Amplified and filtered measurement signal S_{f} corresponds to the difference between the two amplified measurement signals Sₐₘₚ obtained for the two pulses I+ and I−. An advantage of this embodiment is that it does not require measurement of a compensation signal needing to be refreshed regularly.

Thanks to a low jitter below one nanosecond, two successive acquisitions sampled at a high rate relative to the signal frequency F, for example 62.5 MS/s (megasamples per second) with 15 bits of resolution can be efficiently subtracted. This removes thermoacoustic signals as well as interference pulse coupling and residual longitudinal axial modes. This differential measurement also doubles the useful magnetic signal and thus the sensitivity of probe 20.

The two current pulses I+ and I− need to be opposite but identical in absolute value at 99.8% in order to divide the thermoacoustic noise by a reduction factor equal to 500. This is the maximum reduction factor that can be obtained since, taking for simplification two opposite sine waves I+ and I−, very slightly offset in time by a delay equal to the jitter, the relative residual signal rate after subtraction is equal to 2·π·F·jitter is 0.18% if the jitter is equal to 0.4 ns rms and frequency F is equal to 700 KHz.

Then, if the duration Δt_{d} between the two opposite pulses I+ and I− is sufficiently short, for example equal to 1 ms, the slow diffusion of heat flows appearing in conductive wire 50 during successive pulses I+ and I− pulses does not have time to significantly change the temperature of the tip 42 of tapered guide 40 between two successive pulses to the point of generating a transit time variation greater than the jitter (that is, approximately 0.4 ns rms) between the two successive opposite pulses I+ and I−. This compensation is thus much more effective than that which consists of recording the compensation signal in a zero gauss cavity and then subtracting this signal from the subsequent measurements in the presence of a field B_{z} to be measured. It is also more effective than a compensation which consists of acquiring measurements with 1,000 successive pulses I+ averaged in a first direction of the current, and then 1,000 successive pulses I− averaged in the opposite direction of the current. Indeed, by interleaving the opposite pulses I+ and I−, the thermal conditions of tip 42 for the two successive pulses I+ and I− are always virtually the same.

According to an embodiment, a succession of bipolar pulses is generated, after which an average of the pairs of measurement signals S corresponding to opposite pulses is performed to refine the resolution with a possible temporal alignment of the acquisition pairs when the temperature variation is strong and rapid.

In order to be able to temporally align a pair of measurement signals S as a response to opposite pulses with respect to other pairs of measurement signals S, the transit time Tr in tapered guide 40 is determined as a function of temperature. For this purpose, detection system 10 is used in direct mode for the transmission of an acoustic wave by electroacoustic transducer 60 into tapered guide 40, and then detection system 10 is used in the reciprocal operating mode for the measurement by electroacoustic transducer 60 of the reflected acoustic wave, also known as the echo. The duration between the time of transmission of the acoustic wave by electroacoustic transducer 60 and the reception of the acoustic wave which has reflected on the tip 42 of the tapered guide corresponds to twice transit time Tr.

A third test was performed. In the third test, the probe 20 used for the first test is used, with the difference that the height of tapered guide 40, measured along its axis of revolution D, is equal to 84 mm.

FIG. 12 is a timing diagram of the amplified measurement signal Sₐₘₚ measured by detection system 10 when an acoustic wave is transmitted by electroacoustic transducer 60 and the reflected acoustic wave is measured by the electroacoustic transducer 60. In FIG. 12, electroacoustic wave 60 is transmitted at the initial time to equal to 0 μs, and the peaks P of signal Sₐₘₚ correspond to the reflected wave reaching electroacoustic transducer 60. The duration elapsing between the initial time to and the first peak of the amplified measurement signal Sₐₘₚ corresponds to twice transit time Tr.

Numerous pairs of measurement signals S are then acquired by using bipolar current pulses, and the pairs of measurement signals S obtained are averaged, taking a first pair of measurement signals S as a reference pair and temporally aligning the other successive pairs of measurement signals S relative to this first pair of measurement signals S based on the maximum of the cross-correlation function between the first pair of measurement signals S and the successive pairs of measurement signals S. This requires for the signal sampling frequency to be sufficiently high for the period between two samples to be small as compared with the period of the signal, typically at least 10 times smaller, and preferably fifty to 100 times smaller. Thus, for an ultrasonic signal centered on 700 kHz, a 62.5-MHz sampling frequency (or MSPS) corresponding to a period of 16 ns is 89 times higher than the ultrasonic frequency and is a good configuration for averaging successive pairs of measurement signals S. Nevertheless, the 16-ns period remains large as compared with the jitter of the pulse generator, smaller than 0.4 ns rms, and as compared with the time shift between the two members of a pair of measurement signals S.

The conditions which will require a temporal alignment between measurement signals S need to be strict, that is, generate temperature differences of several degrees Celsius inside tapered guide 40 between the first pair of measurement signals S and the pair for which a first 16-ns shift would be required. If an average is calculated over 1,000 pairs within 1 second, it can be calculated that the temperature rise of a conductive wire 50 having a diameter d₁ equal to 100 μm in which a current I of 13.3 A is circulated for 0.5 μs under adiabatic conditions increases by less than 20° C. between the first pulse and the 2,000^{th} pulse. This will correspond to a shift by less than 5 sampling periods or 80 ns, which remains near 18 times smaller than the acoustic period. Further, for a pair of opposite traces, the temperature rise of conductive wire 50 between two pulses as close as possible to each other under adiabatic conditions is below 0.01° C. If this temperature rise were that of tapered guide 40, this rise would amount to a transit time variation nearly ten times smaller than the 0.4-ns jitter. In practice, the heat generated in conductive wire 50 diffuses throughout the volume of tapered guide 40 and the temperature rise of the assembly is much lower. However, if the pulse current is increased to 67 A, then the heating of conductive wire 50 under adiabatic conditions will be 25 times greater. This heating will initially spread to the end of the tip 42 of tapered guide 40, generating a variation in the transit time Tr of the wave packet, and the alignment may be useful for successive signal pairs to remain in phase on the long term (on a scale of one second) and for the averaging to remain advantageous to improve the signal-to-noise ratio.

Knowing that measurement signal S is sampled with a sampling period Ts equal to 1/Fs, where Fs is the sampling frequency, if the temperature-related offset relative to a reference signal corresponding to a reference temperature or a first reference measurement signal S is greater than one sampling period, then a corrective time shift in the opposite direction is applied to subsequent measurement signals S in order to average the measurement signals. The sampling frequency of the signal is in practice greater than 12 times the ultrasonic frequency and preferably greater than 100 times the ultrasonic frequency, which implies a sampling frequency of approximately 100 MSPS (MegaSamplePerSecond), that is, a sampling period Is equal to 10 ns.

In practice, the sensitivity of probe 20 increases linearly with the intensity of the measurement current I, while the thermoacoustic noise signal increases with the square of current I. There thus exists a current threshold value above which thermoacoustic noise can no longer be compensated for, either due to jitter or due to saturation of the analog-to-digital converter scale or even a lack of resolution of the analog-to-digital converter. The residual thermoacoustic noise after compensation then becomes visible when it reaches the shot noise (Nyquist noise) generated by the resistive network measured at the output of receiver amplifier 35 (Nout). If the latter is, for example, 0.5 mV rms after a 66-dB gain (2,000 linear), then there is no point in further increasing the intensity of the measurement current except if it is desired to decrease the measurement time, which linearly decreases the thermoacoustic noise.

FIG. 13 shows a curve of variation of the noise due to the thermoacoustic effect Nout and a curve of variation SB of sensitivity as a function of the intensity of the pulses of current I. The curves are obtained by averaging 1,000 successive acquisitions.

As an example, it can be seen in FIG. 13 that when the noise Nout at the output of receiver amplifier 35 after a 66-dB gain is 0.5 mV rms, the sensitivity SB of probe 20 for a measurement based on two opposite current pulses with a 13.3-A amplitude reaches 120 V/T, with as a model in differential mode SB equal to 9·I (SB expressed in V/T and I in amperes) and the thermoacoustic noise Nout equal to 2.8·I² (Nout in μV and I in amperes).

The ultimate resolution of system 10 can then be calculated and for Nout/SB estimated equal to 500 μV/120 (μV/μT), that is, 4.2 μT. If the current is increased by a factor 5 and the pulse duration is decreased by a factor 6 to approximately 100 ns, then the ultimate resolution degrades by a factor from approximately 4 to 20 μT. Similarly, with a conductive wire 50 having a diameter d₁ equal to 100 μm arranged on a tapered guide 40 having the shape of a truncated cone with its bearing surface 44 having a diameter de equal to 0.2 mm, the magnetometric sensitivity area is at best approximately 0.4 mm by 0.1 mm.

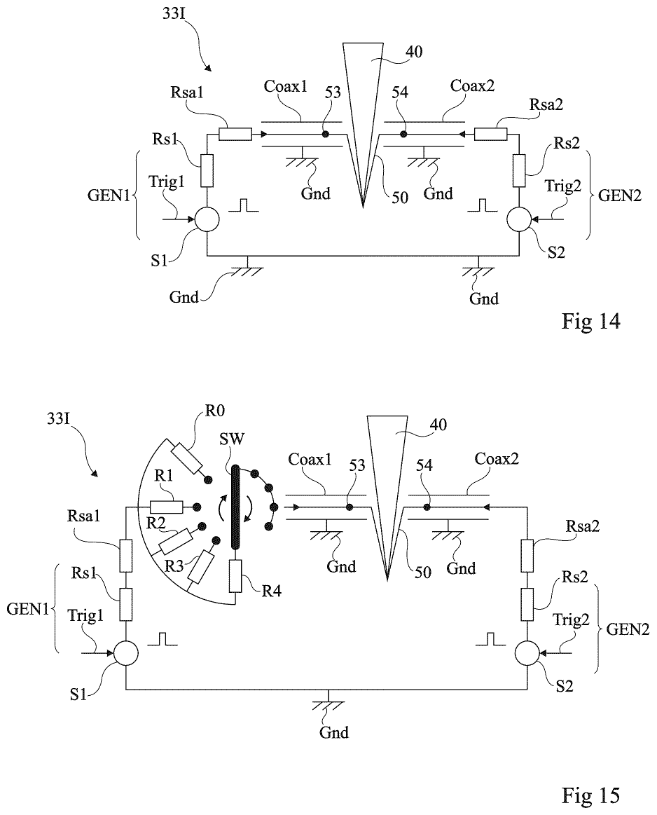

FIG. 14 is an electrical diagram of an embodiment of the current pulse generator 331 of the detection system 10 of FIG. 7.

According to an embodiment, current pulse generator 33I comprises:
a first pulse generator GEN1 comprising a first voltage pulse source S1, controlled by a first control signal Trig1, and having a first terminal coupled, preferably connected, to a source of a low reference potential Gnd, for example ground, of detection system 10 and a second terminal coupled, preferably connected, to a first output resistor Rs1;
a first current-limiting resistor Rsa1 having a first terminal coupled, preferably connected, to the first pulse generator GEN1;
a first coaxial cable Coax1 having its shielding coupled, preferably connected, to the source of the low reference potential Gnd, having a first terminal coupled, preferably connected, to the first resistor Rsa1 and having a second terminal coupled, preferably connected, to a first end 53 of conductive wire 50;
a second pulse generator GEN2 comprising a second voltage pulse source S2, controlled by a second control signal Trig2, and having a first terminal coupled, preferably connected, to the source of the low reference potential Gnd of detection system 10 and a second terminal coupled, preferably connected, to a second output resistor Rs2;
a second current-limiting resistor Rsa2 having a first terminal coupled, preferably connected, to the second pulse generator GEN2; and
a second coaxial cable Coax2 having its shielding coupled, preferably connected, to the source of low reference potential Gnd, having first terminal coupled, preferably connected, to the second resistor Rsa2, and having a second terminal coupled, preferably connected, to a second end 54 of conductive wire 50.

Preferably, the first pulse generator GEN1 is identical to the second pulse generator GEN2. In particular, when the pulse generators GEN1 comprise MOS transistors, the same type of MOS transistors (for example, with an N or P channel) is used for each pulse generator GEN1 and GEN2. The generators GEN1 and GEN2 are adapted to supplying voltage pulses equal to, for example, 60 V. Generators GEN1 and GEN2 are triggered by control signals Trig1 and Trig2, which are logic signals with a typical width equal to 100 ns, an amplitude equal to, for example, 3.3 V, and a short switching time typically shorter than 16 ns and preferably shorter than 5 ns. The duration of the voltage pulses delivered by pulse generators GEN1 and GEN2 is programmable. Generators GEN1 and GEN2 comprise the same paired components (resistors, transistors) with characteristics equal to within 0.1% in order to produce voltage pulses generally identical to within 0.2%. Generators GEN1 and GEN2 can source or sink current with a low output impedance, typically equal to 0.2 ohms.

Pulse generators GEN1 and GEN2 can inject or sink current. When current is desired to be conducted in conductive wire 50 in one direction, source S1 is activated and injects current, while the output of source S2 is switched to ground Gnd and sinks current. To reverse the direction of the current, the output of source S1 is switched to ground Gnd, while source S2 is activated. Both sources S1 and S2 can either source or sink current. They operate synchronously with their own control signals Trig1 and Trig2, which activates them for a duration Δt.

The current pulses are fed to conductive wire 50 via coaxial cables Coax1 or Coax2, which advantageously limit parasitic inductive and capacitive coupling, particularly with amplifier 35. The two resistors Rsa1 and Rsa2 are identical. As an example, each resistance Rsa1 and Rsa2 is in the range from 0 ohm to 2 ohms, and is preferably equal to 1 ohm. The two resistors Rsa1 and Rsa2 aim at limiting the maximum current to be sunk by each of generators GEN1 and GEN2 when it undergoes current injection from the other generator, the injection capacity being potentially greater than the sinking capacity, current limitation enables to avoid exceeding the sinking capacity and to maintain a good similarity between opposite pulses.

The direction of the current generated in conductive wire 50 depends on the pulse generator GEN1 or GEN2 which is active. Pulse generators GEN1 and GEN2 are never active at the same time.

According to an embodiment, pulse generators GEN1 and GEN2 are alternately active, each generating a single positive current pulse of duration Δt. Duration Δt is preferably equal to half the period of electroacoustic transducer 60. The current pulse emitted by one of pulse generators GEN1 and GEN2 is spaced apart from the current pulse emitted by the other pulse generator GEN1 and GEN2 by an interval 1/PRF (where PRF designates the pulse repetition frequency for performing the differential measurement). Interval 1/PRF may be in the range from 0.1 ms to 100 ms and is preferably equal to approximately 1 ms.

According to another embodiment, pulse generators GEN1 and GEN2 are activated so as to generate a bipolar pulse having a center frequency which is preferably that of electroacoustic transducer 60. The measurement sensitivity is thus increased at the cost of an increase in the sampling time of magnetic field B_{z}. For example, a bipolar pulse may be triggered (which is achieved by a pulse of control signal Trig1 followed by a pulse of control signal Trig2), the two pulses being spaced apart by a duration equal to 0.5 μs, and then, 1 ms later, a second opposite bipolar current pulse (which is obtained by a pulse of control signal Trig2 followed by a pulse of control signal Trig1), used to implement the differential measurement.

According to another embodiment, pulse generators GEN1 and GEN2 are activated so as to produce bursts of pulses comprising a train of current pulses, for example, in the order (Trig1, Trig2, Trig1, Trig2) followed by a train of current pulses (Trig2, Trig1) for the Trig1, Trig2, differential measurement with slightly different programmable durations for each of the pulses of pulse generator GEN1 (and thus of pulse generator GEN2), slightly greater or smaller than the center period of electroacoustic transducer 60, the reason for which will be explained later in the implementation of the pulse compression technique.

In the above-described embodiments, control signal Trig1 or Trig2 only triggers a positive rectangular pulse with a programmable width and delay. As a variant, control signals Trig1 or Trig2 can each trigger a burst of positive pulses, each pulse in the burst being defined by its rise time relative to the rising edge of control Trig1 or Trig2 signal and its duration being defined as an integer number of periods of a high-frequency clock operating, for example, at 150 MHz. Thus, a pulse having a duration equal to 700 ns starting 6.67 ns after signal Trig1 or Trig2 will correspond to a delay by 1 period of the high-frequency clock and a duration of 105 periods of the high-frequency clock. An entire pulse train can be defined in this way based on a single control signal Trig1 or Trig2.

FIG. 15 is an electrical diagram of another embodiment of the current pulse generator 33I of the detection system 10 of FIG. 7.

The current pulse generator 33I shown in FIG. 15 comprises all the elements of the current pulse generator 33I shown in FIG. 14 and further comprises resistors R0, R1, R2, R3, and R4, each having t terminal coupled, preferably connected, to resistor Rsa1, and comprises a switch SW configured to connect the second terminal of one of resistors R0, R1, R2, R3, and R4 to coaxial cable Coax1. Switch SW may be a rotary mechanical selector. Resistors R0, R1, R2, R3, and R4 have different values.

Resistances R0, R1, R2, R3, and R4 enable to select a measurement scale. As an example, Rsa1 and Rsa2 are equal to 0.5 ohms, R0 is equal to 0 ohms, R1 is equal to 3.1 ohms, R2 is equal to 84 ohms, R3 is equal to 856 ohms, and R4 is equal to 8,570 ohms. Resistance R0 enables to obtain the highest current pulses, while resistances R1, R2, R3, and R4 select respective ranges Range1 to Range4 as shown in the following Table 1 with a current pulse duration equal to 0.7 μs.

TABLE 1

| Parameters | Range1 | | Range2 | | Range3 | | Range4 | |
|---|---|---|---|---|---|---|---|---|
| Sensitivity | 120 | | 7 | | 0.7 | | 0.07 | |
| (V/T) | | | | | | | | |
| Intensity | 13.3 | | 0.7 | | 0.07 | | 0.007 | |
| (A) | | | | | | | | |
| Noise (Nout) | 500 | | 1.37 | | 0.014 | | 0.00014 | |
| (μV) | | | | | | | | |
| Equivalent | 2,100 | | 100 | | 10 | | 1 | |
| TAN field | | | | | | | | |
| (μT) | | | | | | | | |
| Equivalent | 4.2 | | 0.2 | | 0.02 | | 0.002 | |
| Nout field | | | | | | | | |
| (μT) | | | | | | | | |
| Detectivity | 4.2 | | 71 | | 714 | | 7143 | |
| (μT) | | | | | | | | |
| Compensation | YES | | NO | | NO | | NO | |
| required? | | | | | | | | |
| Max B_{z} | 1,000 | | 2,000 | | 2,000 | | 2,000 | |
| sampling (Hz) | | | | | | | | |
| Measurement | 0.004 mT- | | 14 mT- | | 140 mT- | | 1.4 T- | |
| range | 14 mT | | 140 mT | | 1.4 T | | 40 T | |
| Pico 5242A | +/−2 | V | +/−1 | V | +/−1 | V | +/−1 | V |
| scale | | | | | | | | |
| 15-bit Pico | 122 | μV | 61 | μV | 61 | μV | 61 | μV |
| resolution | | | | | | | | |
| Nout rms | 500 | μV | 500 | μV | 500 | μV | 500 | μV |
| average: 1,000 | | | | | | | | |
| Resolution (% | <0.03 | | <0.05% | | <0.051% | | <0.024% | |
| of max range) | | | | | | | | |
| B_{z}*I (T.A) | 0.19 | | 0.1 | | 0.1 | | 0.28 | |
| Acoustic | <85 | dB | <85 | dB | <85 | dB | <86 | dB |
| pressure at | | | | | | | | |
| end (at Vmax) | | | | | | | | |

In the above table, the equivalent TAN field is the magnetic field corresponding to the thermoacoustic noise level observed without compensation. The detection limit displayed in the above table corresponds to a 1-Hz bandwidth and a compromise on the field sampling time, which remains shorter than one microsecond. For static fields, the resolution can be increased via a larger number of averaged measurements and thus longer acquisition periods.

Advantageously, the intensity of current I decreases with the increase of the field B_{z} to be measured so that product B_{z}*I is smaller than 0.28 A.T. and generates no audio or electrical safety issues.

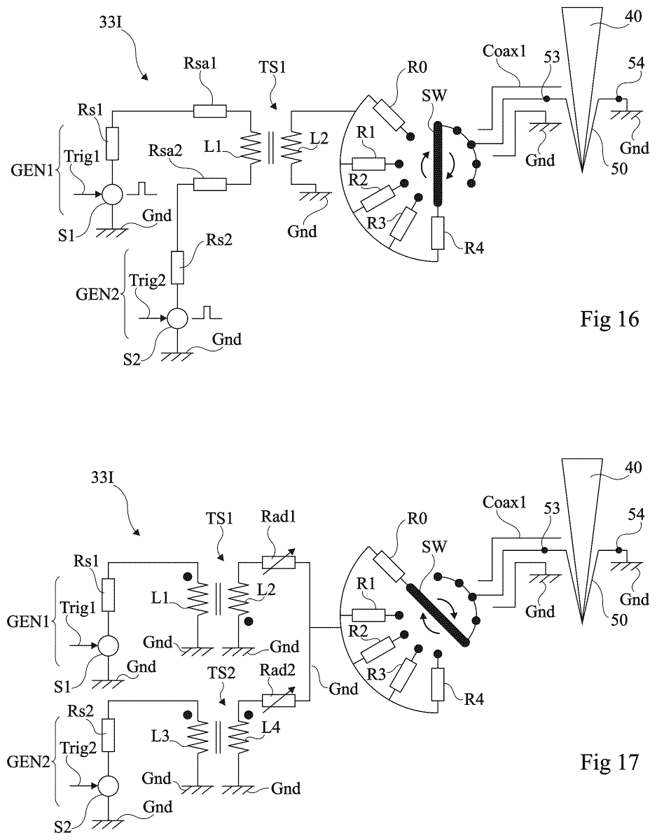

FIG. 16 is an electrical diagram of another embodiment of the current pulse generator 331 of the detection system 10 of FIG. 7.

The current pulse generator 331 shown in FIG. 16 comprises all the elements of the current pulse generator 331 shown in FIG. 15, with the difference that coaxial cable Coax2 is not present, that the end 54 of conductive wire 50 is coupled, preferably connected, to the low reference potential source Gnd, and that it further comprises an isolation transformer TS1 comprising a primary winding L1 and a secondary winding L2, resistor Rsa1 being coupled, preferably connected, to a first terminal of primary winding L1 and resistor Rsa2 being coupled, preferably connected, to a second terminal of primary winding L1, the first terminal of each resistor R0, R1, R2, R3, and R4 being coupled, preferably connected, to a first terminal of secondary winding L2, and a second terminal of secondary winding L2 being coupled, preferably connected, to the source of low reference potential Gnd. According to an embodiment, the inductance of the primary winding L1 of isolation transformer TS1 is in the range from 0.5 μH to 10 μH, and is preferably equal to 1 μH.

The inductive load formed by the primary winding L1 of isolation transformer TS1 is imposed on positive pulse generators GEN1 and GEN2. Transformer TS1 is preferably a voltage step-down transformer with a transformation ratio in the range from 0.25 to 1 so as to be able to increase or maintain a high current at the output of secondary winding L2. According to an embodiment, the number of spirals of primary winding L1 is in the range from 5 spirals to 20 spirals, and the number of spirals of secondary winding L2 is in the range from 5 spirals to 20 spirals. Transformer TS1 limits the maximum power to be supplied by pulse generators GEN1 and GEN2, which have their outputs connected to primary winding L1. The direction of the current generated in secondary winding L2 depends on the active pulse generator GEN1 or GEN2.

This embodiment thus advantageously enables to use a single coaxial cable Coax1. It also enables to generate current pulses identical in absolute values while more easily managing the shielding of the pulse current signal all the way to the vicinity of the end of tapered guide 40.

FIG. 17 is an electrical diagram of another embodiment of the current pulse generator 331 of the detection system 10 of FIG. 7.

The current pulse generator 331 shown in FIG. 17 comprises all the components of the current pulse generator 331 shown in FIG. 16, with the difference that resistors Rsa1 and Rsa2 are not present, that pulse generator GEN1 is coupled, preferably connected to a first terminal of the primary winding L1 of transformer TS1, that a second terminal of the primary winding L1 of transformer TS1 is coupled, preferably connected, to the source of low reference potential Gnd, that it further comprises a potentiometer Rad1, that the first terminal of each resistor R0, R1, R2, R3, and R4 is coupled, preferably connected, to a first terminal of potentiometer Rad1, that a second terminal of potentiometer Rad1 is coupled, preferably connected, to the first terminal of the secondary winding L2 of transformer TS1, that a second terminal of the secondary winding L2 of transformer TS1 is coupled, preferably connected, to the source of low reference potential Gnd, that it further comprises an isolation transformer TS2 comprising a primary winding L3 and a secondary winding L4, that pulse generator GEN2 is coupled, preferably connected, to a first terminal of the primary winding L3 of transformer TS2, that a second terminal of the primary winding L3 of transformer TS2 is coupled, preferably connected, to the source of low reference potential Gnd, and that it further comprises a potentiometer Rad2, that the first terminal of each resistor R0, R1, R2, R3, and R4 is coupled, preferably connected, to a first terminal of potentiometer Rad2, that a second terminal of the potentiometer Rad2 is coupled, preferably connected, to a first terminal of the secondary winding L4 of transformer TS2, and that a second terminal of the secondary winding L4 of transformer TS2 is coupled, preferably connected, to the source of low reference potential Gnd.

This embodiment advantageously enables not to impose on generators GEN1 and GEN2 the constraint of parity both for current injection and sinking, but only to impose on generators GEN1 and GEN2 the constraint of parity for current injection.

The two isolation transformers TS1 and TS2 generate opposite voltages having their outputs connected. The two isolation transformers TS1 and TS2 are possibly voltage step-down transformers with a factor 2 to decrease their output impedance by a factor 4. In the absence of a load (the load corresponding to resistors R0 to R4 and conductive wire 50), the output impedances of transformers TS1 and TS2 being identical, the height of the resulting pulses is divided by 2 in output voltages. However, for the case of the strongest currents (concerning R0 and R1), the output impedance of transformers TS1 and TS2 is high with respect to that of the load, so that the current supplied by one of transformers TS1 or TS2 mainly flows into the load and not into the other transformer. In case of a slight difference in the efficiency of the transformers due to their manufacturing (positions of the spirals, etc.), generating a slight difference in their ability to supply currents of identical absolute value, transformers TS1 and TS2 are balanced via the two potentiometers Rad1 and Rad2, which also balance the entire chain, including a possible slight difference between the output impedances of generators GEN1 and GEN2 affecting the amplitude of the current injected into the primary windings L1 and L3 of transformers TS1 and TS2. The resistances of the potentiometers Rad1 and Rad2 are in the range from 0.001 ohms to 2 ohms, and preferably smaller than 1 ohm. Each inductance of windings L1, L2, L3, L4 ranges, for example, from 0.5 μH to 2 μH. It is preferable to select a minimum number of spirals in order to maximize the power of transformers TS1 and TS2 and obtain a rapid current rise relative to the period of electroacoustic transducer 60.

According to an embodiment, switch SW may comprise reed switches, also known as flexible blade switches, switching via an electromagnet surrounding two opposing blades and controlled by a control signal. The switching times of reed switches are shorter than 1 ms and the contact resistances are smaller than 0.2 ohms, while the switching currents can easily exceed 1 A.

According to an embodiment, the portion 52 of conductive wire 50 covering the tip 42 of tapered guide 40 is locally thinned relative to the rest of conductive wire 50 to decrease the thermoacoustic effect.

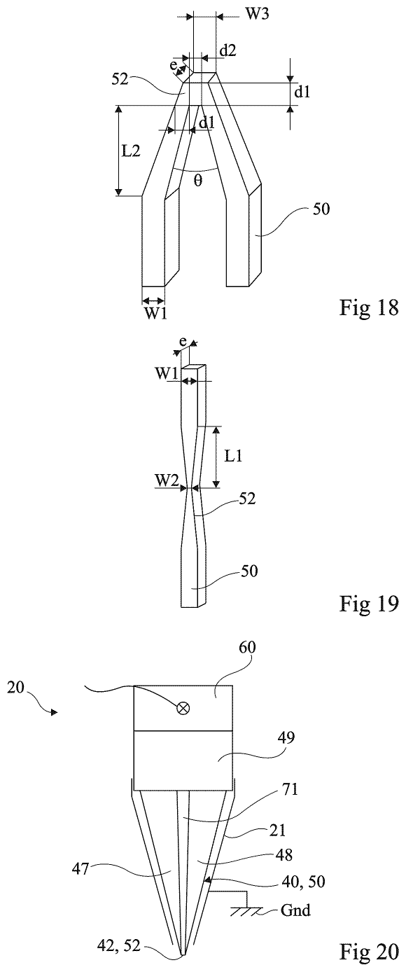

FIG. 18 is a perspective view, partial and simplified, of an embodiment of conductive wire 50 in which portion 52, intended to cover the tip 42 of tapered guide 40, not shown, is thinned, and FIG. 19 is a perspective view, partial and simplified, of conductive wire 50 at an intermediate step of a method of manufacturing conductive wire 50, having its portion 52 thinned.

According to an embodiment, conductive wire 50 is formed in a metal sheet having a thickness, for example, in the range from 50 μm to 300 μm, preferably equal to 100 μm, which is chemically etched by deep etching. Conductive wire 50 has a rectangular cross-section with a base width W1 varying, for example, from 200 μm to 500 μm. When tapered guide 40 is made of a conductive material, the tip 42 of tapered guide 40 may be anodized with a layer of alumina (Al₂O₃) on a film having a thickness from 5 μm to 20 μm in order to ensure its electrical insulation.

According to an embodiment, the configuration of FIG. 18 is obtained directly as a result of the etch step. Angle θ is greater than the angle at the apex of the cone of tapered guide 40. The thickness of conductive wire 50 of rectangular cross-section also decreases from W1 to d1 along a height L2 typically equal to 12*(W1−d1). Width W3 is equal to d2+2*d1 and width d2 is at least equal to the diameter of the truncated section of tapered guide 40. The configuration shown in FIG. 18 is particularly well suited for coupling by local fusion of a tapered guide 40 made of glass or insertion into a truncated tapered guide 40 made of anodized aluminum with a slot.

The configuration of FIG. 19 is obtained as a result of the etch step at an intermediate step of the method of manufacturing conductive wire 50. Width W1 is decreased to a width W2 in the range from 50 μm to 200 μm and preferably equal to 100 μm along a length L1 equal to from 5 to 15 times the difference between W1 and W2, preferably 12 times, that is, equal to 1.2 mm when W1 is equal to 200 μm and W2 is equal to 100 μm. It is then sufficient to fold in half conductive wire 50 at the neck of width W2 and to mount it at the end of a tapered guide 40.

FIG. 20 is a cross-section view, partial and simplified, of an embodiment of probe 20 enabling to decrease the thermoacoustic effect.

In this embodiment, tapered guide 40 is made of a conductive material and incorporates conductive wire 50. For achieve this, tapered guide 40 comprises two guides halves 47, 48 made of an electrically-conductive material, of same dimensions and assembled by means of an electrically-insulating adhesive 71. As a variant, the electrically-insulating adhesive 71 may not be present and be replaced by an air gap. The two guides halves 47, 48 correspond, for example, to two half-cones. As a variant, the two guides halves 47, 48 correspond to two cones. The two guides halves 47, 48 are electrically connected to the pointed end 42 over an extremely limited, almost point-like area forming the tapered portion 52 of conductive wire 50. Each of guides halves 47, 48 thus becomes part of conductive wire 50, having its cross-section linearly decreasing to reach a small cross-section only at the end of the two guides halves 47, 48 forming the tapered portion 52 of conductive wire 50.

Tapered guide 40 further comprises a cylindrical section 49 made of an electrically-insulating material, such as glass or ceramic, bonded to the base of guides halves 47, 48, preferably of same diameter as guides halves 47, 48 when these correspond to half-cones. This enables to spatially isolate the current pulse from ultrasonic transducer 60. The length of cylindrical section 49 is in the range from 1 mm to 20 mm and preferably equal to approximately 10 mm. Section 49 made of electrically-insulating material has an acoustic impedance comparable to that of guides halves 47, 48 made of electrically-conductive material, so that the acoustic transfer between guides halves 47, 48 and cylindrical section 49 is achieved relatively efficiently, with a transverse wave transmission rate that can exceed 70%. Probe 20 may comprise a metal shielding shell 21 surrounding guides halves 47, 48, at a distance from guides halves 47, 48, and connected to the source of low reference potential Gnd. Shell 21 may be fixed to cylindrical section 49.

When guides halves 47, 49 correspond to half-cones, tapered guide 40 may be manufactured by assembly of two metal parallelepipeds of same square cross-section, which are bonded together with electrically-insulating adhesive 71, facing each other on one of their large surfaces, and which are machined to obtain the two half-cones 47, 48 of same dimensions. The two half-cones 47, 48 are then welded to the pointed end 42. Then, the base of half-cones 47, 48 is coupled to cylindrical section 49.

This embodiment enables to significantly decrease thermal expansion and optimizes the efficiency of the generation of the bending wave by the Lorentz force.

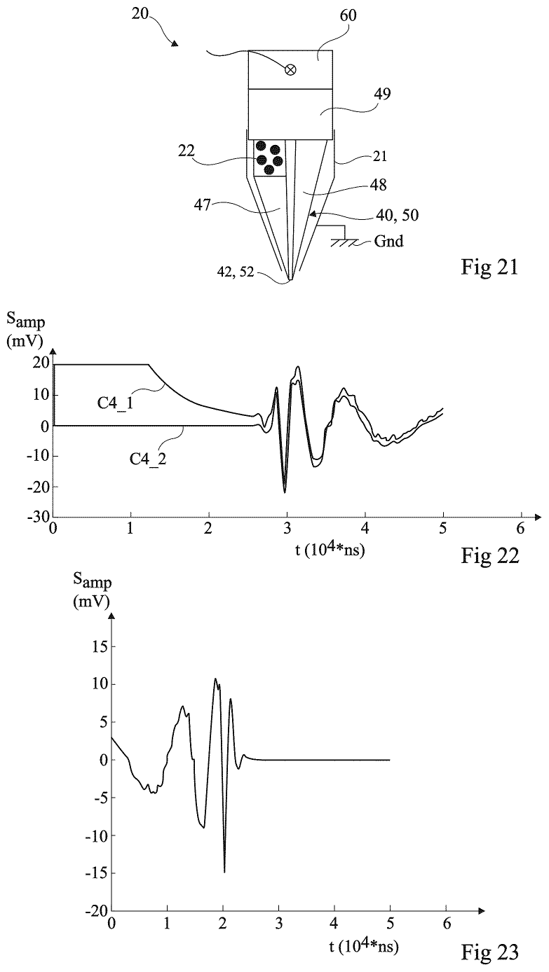

FIG. 21 is a cross-section view, partial and simplified, of another embodiment of the probe 20 of detection system 10 enabling to decrease the thermoacoustic effect.

The probe 20 shown in FIG. 21 comprises all the elements of the probe 20 shown in FIG. 20, with the difference that it further comprises a damping element 22, such as a polymer filled with metal powder, interposed between the base of one of guides halves 47, 48 and section 49. In this case, only one of guides halves 47, 48 is connected to ultrasonic transducer 60. This enables to use a single one of the two guides halves 47, 48 for the transmission of acoustic waves to electroacoustic transducer 60, which is advantageous when the two guides halves 47, 48 are not strictly identical, as a small difference in profile near the end can generate a variation in phase velocity, responsible for a significant phase difference at the base of guides halves 47, 48.

The base of guide half 47, 48 in contact with damping element 22 acts as an acoustic output intended to dampen the signal via damping element 22 and decrease the reverberation time in guides halves 47, 48, and thus allow a higher PRF (Pulse Repetition Frequency) measurement rate.

An embodiment of a method of improving the magnetometric sensitivity of measurement system 10 via a pulse compression signal processing which advantageously takes into account the length of tapered guide 40 and its dispersive properties will now be described. The sensitivity gain obtained by the pulse compression technique may be obtained either via the dispersive effect which occurs during propagation in tapered guide 40, or by creating a train of current pulses comprising a frequency modulation.

An embodiment in which the sensitivity gain obtained by the pulse compression technique is obtained via the dispersive effect will now be described.

In reciprocal operating mode, during the propagation in tapered guide 40 from pointed end 42 to base 41, the bending mode generated at pointed end 42 undergoes a dispersive effect, and while the magnetic field is sampled at the pointed end 42 of tapered guide 40 for a duration equal to the duration Δt of the current pulse, the resulting wave at the base 41 of tapered guide 40 has changed shape and its analysis reveals a spectral distribution with the highest frequencies located at the front of the wave packet and the lowest frequencies located at the end of the wave packet.

This observation is particularly valid if the signal observed across electroacoustic transducer 60 has an electrical load impedance much higher than the impedance relative to the intrinsic capacitance of electroacoustic transducer 60. For example, electroacoustic transducer 60 may have an intrinsic capacitance of 1.8 nF, equivalent to approximately 88 ohms at 1 MHz. If the input impedance of receiver amplifier 35 is significantly higher than this value, for example at least 5 times higher, that is, a value in the range from 470 ohms to 1 kiloohm, then it can be considered that electroacoustic transducer 60 is operating under high load impedance and essentially accounts for the mechanical displacement which propagates along tapered guide 40, which exhibits low frequencies relatively well. On the other hand, in the case where the input impedance of receiver amplifier 35 is lower than 88 ohms, it can be considered that electroacoustic transducer 60 operates under low load impedance, and the amplified measurement signal Sₐₘₚ is more representative of the derivative of the mechanical displacement, and thus of the acoustic velocity, which selects high frequencies.

To implement a pulse compression technique, it is preferable to be in a situation where the wave packet at the output of transducer 60 comprises a frequency-modulated signal and to apply to this signal a matched filtering having a pulse response which is, in practice, the time reversal of the expected shape of the reception signal. A function of intercorrelation of the output signal is thus implemented with a matched filter, which improves the signal-to-noise ratio with a gain theoretically equal to the product of the duration of the frequency-modulated pulse by the frequency band involved in the modulation. To optimize the resolution of measurement system 10, it is preferable to have a broadband electroacoustic transducer 60 and a pulse train modulated in the reception band of electroacoustic transducer 60 with as long a duration as possible, for example, a duration equal to the time of transit in tapered guide 40. It is thus preferable to have a relatively long tapered guide 40.

A fourth test was performed. In the fourth test, the probe 20 used for the first test is used.

FIG. 22 shows timing diagrams C4_1 and C4_2 as a function of time of the amplified measurement signal Sₐₘₚ obtained for the fourth test. Curve C4_1 is obtained for a raw measurement signal Sₐₘₚ amplified with an amplifier 35 saturated at the start by crosstalk during the current pulse due to a lack of shielding and under high impedance. Curve C4_2 is obtained after the implementation of a thermoacoustic effect compensation method such as described hereabove.

FIG. 23 shows a curve of the time variation of the pulse response of the matched filter, that is, the time reversal of analog measurement signal S in compensated mode (cleaned of interference related to the capacitive/inductive coupling at the time of the pulse) in the case of a known high-intensity magnetic field B_{z} to benefit from a good signal-to-noise ratio.

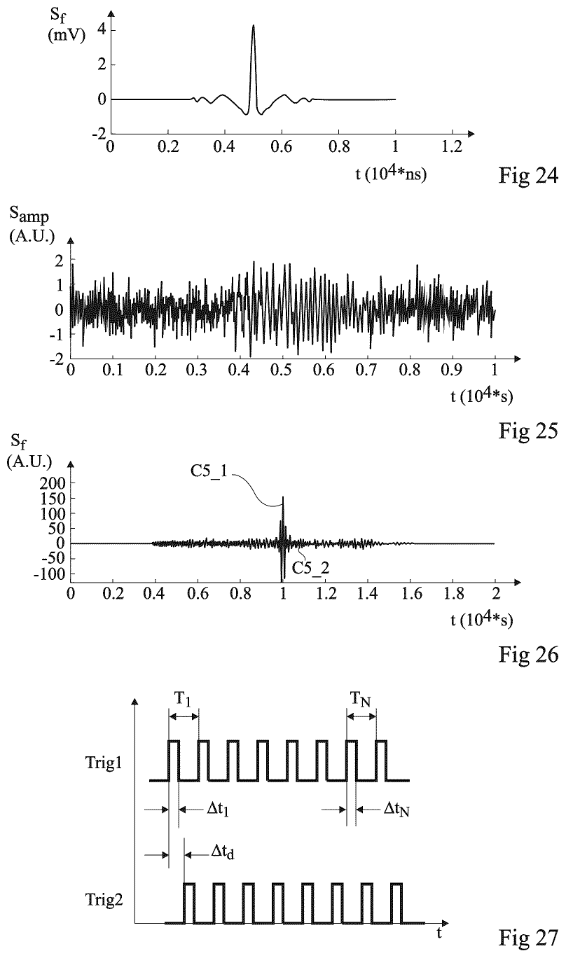

FIG. 24 shows a timing diagram of the amplified and filtered measurement signal S_{f} obtained after the convolution of the signal of curve C4_2 of FIG. 22 with the pulse response of the matched filter of FIG. 23, which generates a function of intercorrelation of the output signal with that of the matched filter. The frequency modulation linked to the dispersive effect in tapered guide 40 generates a pulse compression effect at the output of the matched filter and an improvement in the signal-to-noise ratio, and thus a gain in magnetometric sensitivity. Further, it can be observed that the sign of the maximum of the intercorrelation function is directly representative of the measured magnetic pole. If the latter is the same as the north or south reference field pole, then the peak is positive, otherwise, if the measured pole is opposite, then the sign is negative. This provides a simple way to identify the pole.

An embodiment in which the gain in sensitivity by pulse compression is obtained by creating a current pulse train comprising a frequency modulation will now be described.

A train of current pulses frequency-modulated between an initial frequency and a final frequency is applied and measurement signals S are acquired. The amplified measurement signal Sₐₘₚ is applied a matched filtering corresponding to the time reversal of the frequency modulation function and also a filtering adapted to the noise at the output of amplifier 35 in the absence of a magnetic field.

FIGS. 25 and 26 show timing diagrams, expressed in arbitrary units, obtained by simulation, which illustrate the gain in sensitivity by pulse compression obtained by frequency modulation of a train of sinusoidal current pulses.

For the simulation, the current pulses are sinusoidal and last for 25 μs, that is, a little less than the transit time Tr equal to 27 μs in a tapered guide 40 corresponding to a cone with a height H equal to 84 mm. The current pulses are frequency modulated between an initial 500-kHz frequency and a final 1-MHz frequency, which falls within the bandwidth of electroacoustic transducer 60.

FIG. 25 shows a timing diagram of an example of an amplified measurement signal Sₐₘₚ obtained without filtering on application of the frequency-modulated sinusoidal current pulse train described hereabove. For the simulation, noise is added to amplified measurement signal Sₐₘₚ so that the signal-to-noise ratio of the amplified measurement signal Sₐₘₚ is equal to 2. The added noise is Gaussian noise with a mean of zero and a standard deviation of 0.5 according to a normal distribution.

FIG. 26 shows timing diagrams C5_1 and C5_2 of the amplified and filtered measurement signal S_{f} (curve C5_1) and of the amplified and filtered noise alone (curve C5_2). The signal-to-noise ratio C5_1/C5_2 is 25. The gain in signal-to-noise ratio of the amplified and filtered measurement signal S_{f} is thus equal to 12.5. A gain in sensitivity by pulse compression is obtained by frequency modulation of a train of sinusoidal current pulses. This gain is equal to the product of the modulation bandwidth by the duration of the pulse (0.5 MHz*25 μs).

According to an embodiment, the current pulses are rectangular, preferably with a first-order current rise and fall time.

FIG. 27 is a timing diagram of the frequency-modulated control signals Trig1 and Trig2 enabling to obtain a train comprising a number N of frequency-modulated rectangular pulses, N being an integer ranging, for example, from 2 to 30. The pulses of control signals Trig1 and Trig2 have a duration varying from Δt₁ to Δt_{N} associated with a period varying from T₁ to T_{N} implementing a frequency modulation ΔF, for example between 300 kHz and 1 MHz, in particular around the center frequency F0 of electroacoustic transducer 60, for example equal to 1 MHz. The frequency modulation may not be strictly symmetrical around center frequency F0, but rather performed below the center frequency F0 of the electroacoustic transducer 60 because the focusing of tapered guide 40 degrades rapidly towards higher frequencies and for a given apex angle of tapered guide 40. The pulse trains of control signals Trig1 and Trig2 are constructed from a frequency-modulated sinusoidal signal x(t) starting from the highest frequency F_{N}, equal to 1/T_{N}, and ending at the lowest frequency F₁, equal to 1/T₁, (with ΔF equal to the difference between frequency F_{N} and frequency F₁) at the end of a total time period T_{burst} which does not exceed the time Tr of transit in tapered guide 40. Frequency F_{N} is, for example, equal to 1 MHz. Frequency F₁ is, for example, equal to 300 KHz. Duration T_{burst} is, for example, equal to 24 μs for a tapered aluminum waveguide 40 having a length equal to 85 mm. The sinusoidal signal x(t) is given by the following relation:

$$x ( t ) = sin ( 2 π ( {F}_{N} - ( 0 , 5 \cdot Δ F / {T}_{burst} * t ) ) * t ) ) \qquad [ Math 10 ]$$

with t varying from 0 to T_{burst} in the form of N_{burst} samples of index i/Fss (where Fss is the time sampling frequency, for example equal to 16 MHz). One has N_{burst} equal to T_{burst}*Fss (rounded to the nearest integer) and i is an integer which varies from 1 to N_{burst}. The sinusoidal burst is then mathematically converted into signals Trig1 and Trig2 by means of a level comparator with a positive and negative threshold expressed as a percentage of the maximum of the sine wave. The threshold is typically selected between 5% and 60%, preferably equal to 50% of the maximum of the sine wave. When the sine wave function exceeds the positive threshold, it is rounded to +1, otherwise, it is rounded to zero. The resulting signal has a duty cycle of less than 50%. It is sent into an arbitrary function generator by associating an output amplitude with this signal, for example 3.3 V, which provides signal Trig1. When the sine wave exceeds the −50% negative threshold, it is also rounded to +1, otherwise it is rounded to zero. The resulting signal is sent to the arbitrary function generator with an output voltage also adjusted to +3.3 V, which provides signal Trig2. It can thus be seen that signals Trig1 and Trig2 are not strictly identical due to frequency modulation. Then, taking the case in FIG. 17, the alternated current measurement consists of simultaneously sending in a first phase signals Trig1 and Trig2 to the respective generators GEN1 and GEN2, and then in the opposite alternating phase, signals Trig1 and Trig2 are interchanged by sending signal Trig1 to the synchronization input of generator GEN2 and signal Trig2 to the synchronization input of generator GEN1. The pulse durations Δt₁ to Δt_{N} are thus shorter than or equal to the respective half-periods T₁/2 to T_{N}/2 so that the pulse trains of control signals Trig1 and Trig2 always have a zero temporal intersection.

In the embodiments described hereabove, the pulse compression method is implemented for a measurement system 10 operating in the reciprocal operating mode. However, the pulse compression method may also be implemented for a measurement system 10 operating in direct operating mode.

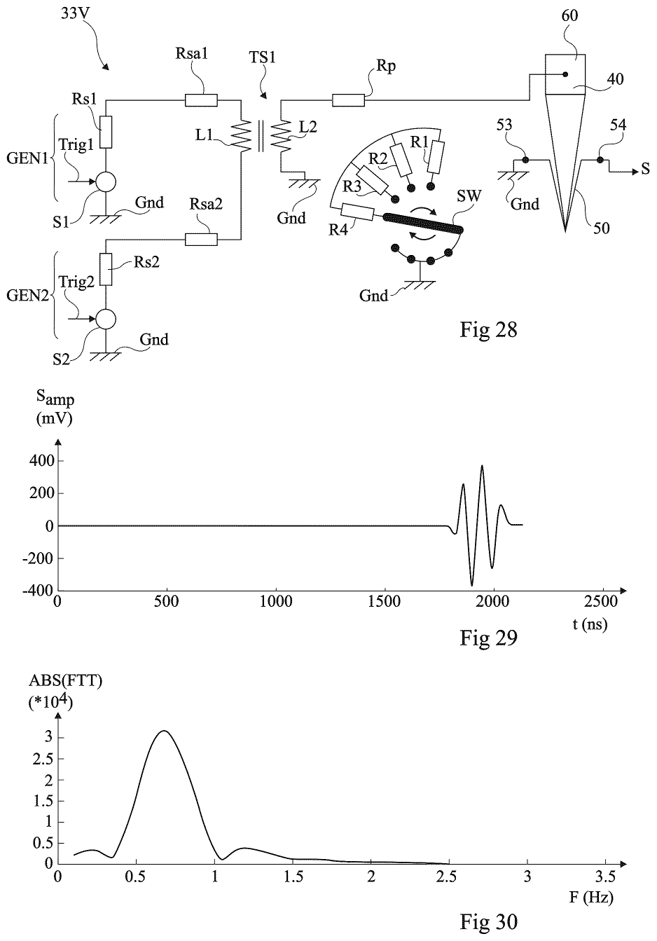

FIG. 28 is an electrical diagram of an embodiment of the voltage pulse generator 33V of the detection system 10 of FIG. 8, enabling to implement the pulse compression method in direct operating mode.

The voltage pulse generator 33V shown in FIG. 28 comprises all the elements of the current pulse generator 33I shown in FIG. 16, with the difference that it further comprises a resistor Rp having a first terminal coupled, preferably connected, to the first terminal of the secondary winding L2 of transformer TS1, that the first terminal of each resistor R1, R2, R3, R4 (resistor R0 not being present) is coupled, preferably connected, to a second terminal of resistor Rp, and is coupled, preferably connected, to a first terminal of electroacoustic transducer 60, and that switch SW couples a second terminal of one of resistors R1, R2, R3, R4 to the source of low reference potential Gnd. It can be observed that in this approach, mechanical switch SW can easily be replaced by a digital switch with four N-channel MOS transistors individually controlled at their gate by a CMOS digital signal, the drains of the N-channel MOS transistors being connected to one of the second terminals of resistors R1, R2, R3, and R4, and the four sources of the MOS transistors being connected to the same low reference potential Gnd.

The control signals Trig1 and Trig2 of generators GEN1 and GEN2 may be those shown in FIG. 27. Sources S1 and S2 generate voltage pulses, for example having an amplitude equal to 60 V, and having durations equal to the pulses Δt₁ to Δt_{N} which are transformed by transformer TS1, for example with a transformation ratio from 4 to 5. The differential detection on two successive opposite acquisitions of current injected into the primary winding L1 of transformer TS1 may also be implemented in order to double the magnetometric sensitivity. The measurement range is defined via a resistor bridge formed by resistor Rp and one of the resistors R1, R2, R3, R4 to which it is connected by switch SW, which varies the amplitude of the voltage applied to electroacoustic transducer 60. The inductance of primary winding L1 is, for example, 2 μH. The inductance of secondary winding L2 is, for example, 16 times the inductance of primary winding L1. Resistance Rp is, for example, 100 ohms. Resistance R1 is, for example, 1 ohm. Resistance R2 is, for example, 10 ohms. Resistance R3 is, for example, 100 ohms. Resistance R4 is, for example, 10 kiloohms.

In direct operating mode, there is no non-linear effect related to the thermoacoustic effect. Measurement signal S is zero in the absence of a magnetic field. However, it is possible to implement a differential measurement on successive acquisitions with pulses of opposite voltages, which has the effect of doubling the sensitivity. Further, it is possible to implement a burst excitation with two generators GEN1 and GEN2 enabling to generate bipolar pulses, which increases the sensitivity. Further, it is possible to implement a pulse compression, which also increases the magnetometric sensitivity. The resolution initially only depends, a priori, on the vibration amplitude, which can lead to creating a very high vibration speed, typically 30 m/s at the tip 42 of tapered guide 40, by means of equally high excitation voltages. This may pose a problem of safety, both electrical and acoustic, given the small size of the tip, which needs to be kept away from the operator's ears. Although the vibration is inaudible and the airborne transmission is very local, the vibratory energy intense and potentially harmful.

As an example, a 10-mV/T sensitivity is obtained with monopolar voltage pulses having a duration equal to 0.5 μs and an amplitude equal to 300 V. This sensitivity can be doubled with bipolar pulses, and doubled again with successive acquisitions of bipolar pulses. It is eventually possible to improve this sensitivity by a factor from 10 to 15 via the sensitivity gain provided by pulse compression, so that a detectivity close to one microTesla and a sensitivity greater than 1,000 V/T can be achieved in direct operating mode.

The linearity of the measurement depends on the processing of measurement signal S and on the selection of a measurement window for measurement signal S. According to an embodiment, the measurement window limited to is a predetermined number of oscillations that end at the time of a zero crossing of reception signal S. For this purpose, any signal value preceding or following this measurement window is canceled. This has the effect of smoothing the fast Fourier transform and of enabling to correctly measure the spectral line of maximum amplitude when working in the Fourier space. The determination of the measurement window is possible whatever the magnetic field and the signal making its way up due to the Lorentz force, because the internal echo in tapered guide 40 is independent of the magnetic field to be measured. It only depends on the temperature distribution in tapered guide 40.

According to an embodiment, to determine the measurement window, the transit time Tr is determined as described hereabove in relation with FIG. 12. As an example, electrostatic transducer 60 is controlled in transmit mode to transmit a wave train with a carrier at the center frequency F0 of electrostatic transducer 60 or possibly frequency-modulated around the center frequency of electrostatic transducer 60. Immediately after transmission, electroacoustic transducer 60 is controlled in receive mode and recovers the internal echo, which is amplified by a gain G2 of a receiver amplifier. Gain G2 is not necessarily very high, or even simply unitary, since a simple sinusoidal pulse with a 10-V peak amplitude is sufficient to generate an echo with a 160-mV peak amplitude. The echo thus has, without amplification, an amplitude of approximately 1 V for a 60-V pulse.

The measurement window is obtained from the transit time Tr thus determined. The determination of transit time Tr can be performed before each magnetic field measurement. According to an embodiment, the measurement window begins after transit time Tr has elapsed after the first voltage pulse implemented to measure the magnetic field, possibly decreased by a margin. The measurement window ends after transit time Tr has elapsed after the last voltage pulse implemented to measure the magnetic field, possibly increased by a margin.

In direct operating mode, in the presence of a magnetic field B_{z} to be measured, there appears across conductive wire 50 a voltage which is amplified with receiver amplifier 35 of gain G1. The measurement signal S appears after a transit time of duration Tr in tapered guide 40 after the first voltage pulse applied to electroacoustic transducer 60. The analysis of the peak amplitude is directly performed by a dedicated electronic module if the dispersive effect in tapered guide 40 is exploited and an excitation which is as close as possible to the time reversal of the signal recovered across conductive wire 50 in the case of a pulse response (that is, a very short pulse before the period 1/F0 of electroacoustic transducer 60). If the dispersive effect of tapered guide 40 is not taken into account and, for example, a frequency-modulated wave train is generated, then the signal needs to be digitized after amplification G2 with a number of samples limited to the measurement window, for example 62.5 samples/μs. Then, the digitized signal is convolved by a reference signal, which is the time reversal of a signal obtained with a magnetic field B_{z} of known value used as a reference. It is then sufficient to measure the value of the maximum amplitude of the obtained signal, which is taken down to the value of the maximum amplitude of the reference signal without time reversal and convolved with itself (that is, the autocorrelation of the reference signal). The magnetic field B_{z} to be determined is then directly the value of this ratio multiplied by reference magnetic field B_{z}.

A simulation was performed in which measurement system 10 is used in direct operating mode for the measurement of a magnetic field with an amplitude equal to 480 mT. Electroacoustic transducer 60 is controlled with a burst of two voltage pulses.

FIG. 29 shows a timing diagram of amplified measurement signal Sₐₘₚ which was set to zero before and after the measurement window, and FIG. 30 shows a curve of the Fourier transform ABS (FFT) of the amplified measurement signal Sₐₘₚ Of FIG. 29.

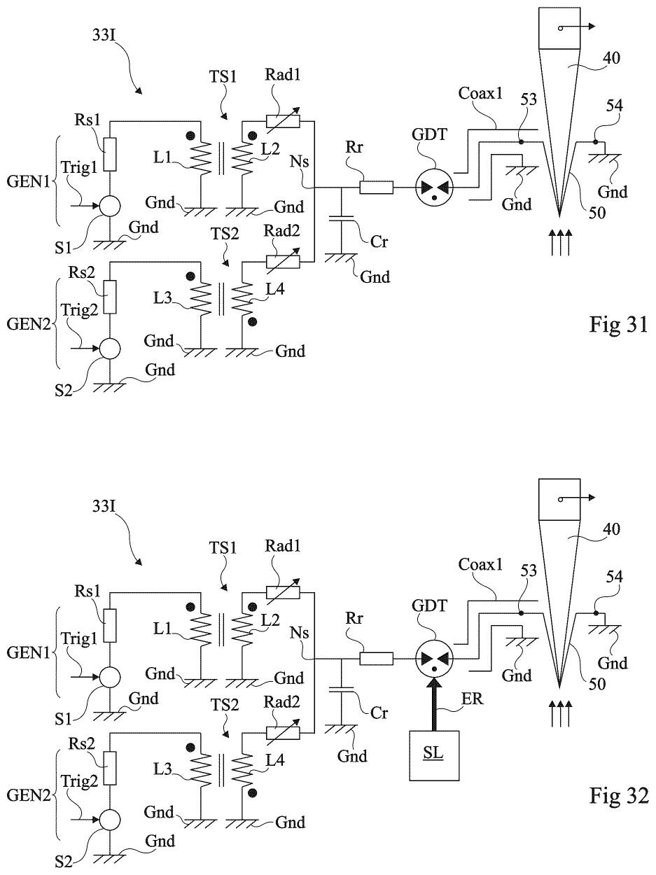

FIG. 31 is an electrical diagram of another embodiment of the current pulse generator 331 of the detection system 10 of FIG. 7, enabling to sample magnetic field B_{z} with an ultra-short period, for example shorter than 5 ns.

The current pulse generator 331 shown in FIG. 31 comprises all the components of the current pulse generator 331 shown in FIG. 17, with the difference that resistors R0, R1, R2, R3, and R4 are not present, that switch SW is replaced by a gas discharge tube GDT having a first terminal coupled, preferably connected, to the conductive wire of coaxial cable Coax1, that it further comprises a capacitor Cr having a first electrode coupled, preferably connected, to resistors Rad1 and Rad2 and a second electrode coupled, preferably connected, to the source of low reference potential Gnd, and that it further comprises a resistor Rr having a first terminal coupled, preferably connected, to resistors Rad1 and Rad2 and a second electrode coupled, preferably connected, to a second terminal of gas discharge tube GDT. Ns is the midpoint between resistors Rad1 and Rad2. The braid of coaxial cable Coax1 is connected to low reference potential Gnd in order to decrease radiation from the conductive wire.

The current pulse generator 331 shown in FIG. 31 is adapted to generating a very short, high-intensity current pulse to take into account the fact that it is being moved away from the optimal value of a pulse duration equal to half the resonance period of electroacoustic transducer 60 while implementing compensation for the electroacoustic effect by current pulses in opposite directions.

Transformers TS1 and TS2 are voltage step-up transformers having a same transformation ratio but opposite signs. Transformers TS1 and TS2 are powered by pulse generators GEN1 and GEN2, which are medium-voltage generators capable of ranging, for example, up to 400 V. These medium-voltage generators GEN1 and GEN2 have low output impedances Rs1 and Rs2, typically lower than 4 ohms, and power transformers TS1 and TS2. Adjustment resistances Rad1 and Rad2, for example smaller than 1 ohm, enable to equalize the absolute values of the positive and negative voltage load slopes of capacitor Cr powered by transformers TS1 and TS2. The rate of voltage increase across capacitor Cr must be as fast as possible and is, for example, between 5 V/ns and 150 V/ns so that the breakdown voltage of gas discharge tube GDT is reached before half a period of electroacoustic transducer 60, that is, less than 500 ns for an electroacoustic transducer 60 having a center frequency resonance equal to 1 MHz. Further, even if the breakdown voltage of gas discharge tube GDT fluctuates by a few tens of volts from one breakdown to another, the slope is sufficiently high for the jitter thus created to be shorter than one nanosecond.

The current excitation of the conductive wire 50 over the tip 42 of tapered guide 40 occurs during the discharge of capacitor Cr via gas discharge tube GDT. The discharge current follows a second-order law defined by the RLC circuit formed by resistor Rr, inductance L2 or L4, and capacitor Cr. For the discharge current pulse to be monopolar, values are selected for resistance Rr and capacitance Cr so that the damping coefficient of this RLC circuit has a value smaller than 1 and preferably close to 0.7. By selecting appropriate values, it is thus possible to obtain a pulse having a width at half maximum smaller than 5 ns and, for example, close to 2.5 ns. To achieve this, a capacitance Cr preferably smaller than 150 pF is selected, so that transformers TS1 and TS2 can have time to charge it within a short time of less than 500 ns, and preferably close to from 50 pF to 100 pF, the conductive wire 50 being located over the tip 42 of tapered guide 40 of short length, minimizing its inductance (preferably smaller than 10 nH) and a series discharge resistance Rr sufficiently high to break the resonance and to ensure that the damping coefficient is close to 0.7 while remaining sufficiently small for the peak current amplitude to reach a high value, for example 100 A, enabling to maximize magnetometric sensitivity. Transformers TS1 and TS2 have a transformation ratio of, for example, 7:90 with 7 spirals in primary winding L1, L3 and 90 spirals in secondary winding L2, L4. A 350-V pulse at the primary winding is thus transformed into a +4500-V or −4500-V pulse at the output of the secondary winding (in open circuit) depending on whether transformer TS1 or TS2 is an inverter or not. Given that transformers TS1 and TS2 are connected to small adjustment resistors Rad1 and Rad2 (less than 1 ohm) and, above all, that they form a load for each other with identical output impedances, the pulses lose half their amplitude at node NS once transformers TS1 and TS2 are connected via adjustment resistors Rad1 and Rad2.

At node Ns, there occurs a pulse capable of reaching a limiting value close to +2,250 V when generator GEN1 is active, or close to −2,250 V when generator GEN2 is active. These limiting voltages are at least 10% higher than the breakdown voltage of gas discharge tube GDT, so that it is always certain to reach the breakdown voltage of gas discharge tube GDT. There are various types of gas tubes commercially available in SMD (surface mount device) format with breakdown voltages specified for a 1-V/ns slope, that can be typically selected between 600 V and 5,000 V. As a variant, gas discharge tube GDT may be formed by a simple copper track, cut, gold-plated, and topped with a sealed cap which will be used as a gas discharge tube, with air acting as the dielectric and the cap having the role of confining the ozone created during the discharge. A device capable of generating high-intensity monopolar pulses that can be alternated to perform a differential measurement to compensate for the thermoacoustic effect is thus obtained. The pulse compression technique here is less advantageous when implementing an ultra-short sampling intended to access high-frequency, broad-spectrum magnetic fields. The high 100-A current flowing through conductive wire 50 enables to maintain a 8.6-V/T sensitivity and a 86-μT detectivity by compensation of the thermoacoustic effect. This assumes that the activation time of the transient magnetic field to be measured can be controlled so that its measurement is synchronous with the current pulse and a jitter shorter than half a nanosecond to be able to implement an alternated opposite pulse current measurement. It is also assumed that the rate of voltage rise at the transformer output is sufficiently high (preferably higher than 100 V/ns) for the fluctuation of the breakdown voltage of gas discharge tube GDT to remain shorter than half a nanosecond.

FIG. 32 is an electrical diagram of a variant of the current pulse generator 331 of FIG. 31.

The current pulse generator 331 shown in FIG. 32 comprises all the components of the current pulse generator 331 shown in FIG. 31 and further comprises a source SL configured to emit an electromagnetic radiation ER toward gas discharge tube GDT, for example a light source or a UV laser source, enabling to actively trigger gas discharge tube GDT. This enables to precisely control the discharge at the desired time and voltage synchronously with a delay ΔTF relative to control signals Trig1 and Trig2 and before the voltage reaches the fluctuating self-triggering threshold causing jitter.

The ER radiation, for example, has an energy ranging from 0.1 mJ to 1 mJ and reaches the electrodes of the gas discharge tube or a target material such as a zinc foil arranged in the immediate vicinity of the electrodes, preferably less than one millimeter away from the electrodes, intended to receive the focused laser impact to generate by ablation a plasma in the immediate vicinity of the electrodes, which triggers the synchronous discharge of gas discharge tube GDT. The laser may be a pulsed laser preferably having a short wavelength, for example shorter than 0.4 μm, and is characterized by a jitter of less than half a nanosecond, pulse durations typically in the range from 5 ns to 10 ns, and a firing rate in the range from 50 Hz to 2,000 Hz.

Examples of applications of the embodiments of the magnetic field measurement system described hereabove concern in particular the study of the electromagnetic compatibility of components, the characterization of inductive components or of high-intensity inductive probes, in particular the spreading of field lines at a distance or electromagnetic leakage through slots or openings in a shielding, or the characterization of the magnetic susceptibility of materials. Another example of an application is the forming of a reader head to map magnetic fields or to read data stored in magnetic form by detection of a local binary polarization or of a field of a given amplitude.

The previously-described embodiments of the magnetic field measurement system enable to synchronously sample a transient or oscillating magnetic field, very local in space and also very local in time via a very short sampling period. In particular, the spatial measurement resolution can be smaller than 0.1 mm, and the sampling time can be shorter than 10 ns, or even 5 ns. It is thus possible, in particular, to measure pulsed magnetic fields with a minimum duration of approximately 10 ns or variable magnetic fields having a maximum frequency in the order of 100 MHz.

Various embodiments and variants have been described. Those skilled in the art will understand that certain features of these various embodiments and variants could be combined, and other variants will occur to those skilled in the art.

Finally, the practical implementation of the described embodiments and variants is within the abilities of those skilled in the art based on the functional indications given hereabove.

1. System for measuring a magnetic field comprising:
a device for detecting the magnetic field, comprising a tapered acoustic waveguide having a base and a tapered end, an electrically-conductive wire rigidly coupled to the tapered end and an electroacoustic transducer rigidly coupled to the base; and
a control and acquisition device coupled to the device for detecting the magnetic field comprising a generator configured to supply a pair of current pulses of opposite directions or a plurality of frequency-modulated current pulses into the electrically-conductive wire and an acquisition circuit configured to detect electrical signals supplied by the electroacoustic transducer or a generator configured to supply a pair of voltage pulses of opposite signs or a plurality of frequency-modulated voltage pulses controlling the electroacoustic transducer and an acquisition circuit configured to detect electrical signals supplied by the electrically-conductive wire.

2. System according to claim 1, wherein the generator is configured to supply a plurality of pairs of current pulses of opposite directions into the electrically-conductive wire or a plurality of pairs of voltage pulses of opposite signs controlling the electroacoustic transducer.

3. System according to claim 1, wherein the generator is configured to supply the pulses having maximum amplitudes in absolute value identical to better than within 2%.

4. System according to claim 1, wherein the frequency modulation of the plurality of frequency-modulated current or voltage pulses is located within the bandwidth of the electroacoustic transducer.

5. System according to claim 1, wherein the acquisition circuit is configured to determine the difference between the electrical signals supplied for the first pulse of the pair of pulses and the second pulse of the pair of pulses.

6. System according to claim 1, wherein the control and acquisition device is configured to determine the time of transit of acoustic waves in the tapered acoustic waveguide between the base and the tapered end, the acquisition circuit being configured to acquire the electrical signals in a time window having its beginning relative to the first of the pulses depending on the transit time.

7. System according to claim 1, wherein the electrically-conductive wire comprises first and second ends, wherein the electroacoustic transducer comprises first and second electrodes, wherein the generator comprises first and second voltage sources, and wherein the first voltage source is coupled to the first end of the electrically-conductive wire or to the first electrode of the electroacoustic transducer.

8. System according to claim 7, wherein the second voltage source is coupled to the second end of the electrically-conductive wire or to the second electrode of the electroacoustic transducer.

9. System according to claim 7, wherein the generator further comprises a first transformer having a first primary winding coupled to the first source and a first secondary winding coupled to the first end of the electrically-conductive wire or to the first electrode of the electroacoustic transducer.

10. System according to claim 9, wherein the second source is coupled to the first primary winding.

11. System according to claim 9, wherein the generator further comprises a second transformer having a second primary winding coupled to the second source and a second secondary winding coupled to the first end of the electrically-conductive wire or to the first electrode of the electroacoustic transducer.

12. System according to claim 7, wherein the generator further comprises resistors of different values and a switch configured to connect in series one of the resistors with the first end of the electrically-conductive wire or with the first electrode of the electroacoustic transducer.

13. System according to claim 7, wherein the generator further comprises a gas discharge tube between the first source and the first end of the electrically-conductive wire or the first electrode of the electroacoustic transducer and a capacitor having a plate coupled to a node between the first source and the gas discharge tube.

14. System according to claim 11, further comprising a device for emitting electromagnetic radiation onto the gas discharge tube.

15. System according to claim 1, wherein the electrically-conductive wire comprises a thinned portion rigidly coupled to the tapered end.

16. System according to claim 1, wherein the tapered acoustic waveguide comprises two tapered acoustic waveguide halves made of an electrically-conductive material and each comprising a pointed end, the two tapered acoustic waveguide halves being distant from each other except for the two tips, which coincide.

17. System according to claim 16, wherein the tapered acoustic waveguide further comprises an electrically-insulating block between the two tapered acoustic waveguide halves and the electroacoustic transducer.
